(19) United States
(12) Patent Application Publication
(10) Pub. No.: US 2024/0321961 A1
(43) Pub. Date: Sep. 26, 2024

(54) INTEGRATED CIRCUIT DEVICE

(71) Applicant: SAMSUNG ELECTRONICS CO., LTD., SUWON-SI (KR)

(72) Inventors: Jongsu Kim, Suwon-si (KR); Myunggil Kang, Suwon-si (KR); Dongwon Kim, Suwon-si (KR); Beomjin Park, Suwon-si (KR); Inhyun Song, Suwon-si (KR); Hyumin Yoo, Suwon-si (KR); Yujin Jeon, Suwon-si (KR)

(21) Appl. No.: 18/613,338

(22) Filed: Mar. 22, 2024

(30) Foreign Application Priority Data
Mar. 24, 2023 (KR) 10-2023-0039015
May 16, 2023 (KR) 10-2023-0063253

(51) Int. Cl. H01L 29/06; H01L 27/092; H01L 29/08; H01L 29/423; H01L 29/775; H01L 29/786

(52) U.S. Cl. CPC H01L 29/0673; H01L 27/092; H01L 29/0847; H01L 29/42392; H01L 29/775; H01L 29/78696

(57) ABSTRACT

An integrated circuit device includes, a first nano-sheet stack including a plurality of nano-sheets arranged on a fin-type active region extending in a first horizontal direction, a gate line extending in a second horizontal direction on the fin-type active region, a vertical structure contacting the plurality of nano-sheets, and a first gate dielectric layer disposed between the gate line and the plurality of nano-sheets and between the gate line and the vertical structure, wherein the gate line includes a first sub-gate portion disposed under each of the plurality of nano-sheets, the first gate dielectric layer includes a first portion disposed between the gate line and the plurality of nano-sheets, and a second portion disposed between the first sub-gate portion and the vertical structure, and a thickness of the second portion in the second horizontal direction is greater than a thickness of the first portion in the vertical direction.

### CROSS-REFERENCE TO RELATED APPLICATIONS

This application is based on and claims priority under 35 U.S.C. § 119 to Korean Patent Application No. 10-2023-0039015, filed on Mar. 24, 2023, and Korean Patent Application No. 10-2023-0063253, filed on May 16, 2023, in the Korean Intellectual Property Office, the disclosures of which are incorporated by reference herein in their entirety.

### TECHNICAL FIELD

The inventive concept relates to an integrated circuit device, and more particularly, to an integrated circuit device including a field-effect transistor.

### DESCRIPTION OF RELATED ART

Integrated circuit devices may be scaled-down to increase efficiency and operation speed. As the integrated circuit devices are scaled-down, it may be necessary to secure the operation speed and an operation accuracy of the integrated circuit devices. Also, as a degree of integration of the integrated circuit devices increases and a size of integrated circuit devices decreases, the possibility of process defects occurring in the manufacturing may increase.

### SUMMARY

The inventive concept provides an integrated circuit device capable of providing stable performance and improved reliability in a nanosheet field effect transistor.

According to an aspect of the inventive concept, there is provided an integrated circuit device. The integrated circuit device includes a first fin-type active region extending in a first horizontal direction on a substrate, a first nano-sheet stack including a first plurality of nano-sheets arranged on the first fin-type active region, a first gate line extending in a second horizontal direction intersecting the first horizontal direction on the first fin-type active region, a vertical structure contacting each of the first plurality of nano-sheets included in the first nano-sheet stack, and a first gate dielectric layer disposed between the first gate line and the first plurality of nano-sheets and between the first gate line and the vertical structure, wherein the first gate line includes a first sub-gate portion disposed under each of the first plurality of nano-sheets, the first gate dielectric layer includes a first portion disposed between the first gate line and the first plurality of nano-sheets, and a second portion disposed between the first sub-gate portion and the vertical structure, and a thickness of the second portion in the second horizontal direction is greater than a thickness of the first portion in a vertical direction.

According to another aspect of the inventive concept, there is provided an integrated circuit device. The integrated circuit device includes a substrate including a first region and a second region, a first fin-type active region extending in a first horizontal direction on the first region, a second fin-type active region extending in the first horizontal direction on the second region and spaced apart from the first fin-type active region in a second horizontal direction intersecting the first horizontal direction, a plurality of nano-sheets on the first fin-type active region and the second fin-type active region and spaced apart from the first fin-type active region and the second fin-type active region in a vertical direction, a first gate line on the first fin-type active region and extending in the second horizontal direction, a second gate line on the second fin-type active region and extending in the second horizontal direction, a vertical structure disposed between the first gate line and the second gate line and contacting each of the plurality of nano-sheets, and a first gate dielectric layer disposed between the first gate line and the plurality of nano-sheets and between the first gate line and the vertical structure, wherein the first gate line comprises: a first main gate portion disposed at a higher vertical level than the plurality of nano-sheets on the first fin-type active region; and a first sub-gate portion disposed under each of the plurality of nano-sheets on the first fin-type active region, the first gate dielectric layer includes a first portion disposed between the first gate line and the plurality of nano-sheets on the first fin-type active region, and a second portion disposed between the first sub-gate portion and the vertical structure, and a thickness of the second portion in the second horizontal direction is greater than the thickness of the first portion in the second horizontal direction.

According to another aspect of the inventive concept, there is provided an integrated circuit device. The integrated circuit device includes a substrate including a first region and a second region, a first fin-type active region extending in a first horizontal direction on the first region, a second fin-type active region extending in the first horizontal direction on the second region and spaced apart from the first fin-type active region in a second horizontal direction intersecting the first horizontal direction, a first nano-sheet stack facing a top surface of the first fin-type active region at a position spaced apart from the top surface of the first fin-type active region and including a first plurality of nano-sheets having different vertical levels, a second nano-sheet stack facing a top surface of the second fin-type active region at a position spaced apart from the top surface of the second fin-type active region and including a second plurality of nano-sheets having different vertical levels, a first gate line and extending in the second horizontal direction on the first fin-type active region, a second gate line extending in the second horizontal direction on the second fin-type active region, a vertical structure disposed between the first gate line and the second gate line and contacting each of the first plurality of nano-sheets and each of the second plurality of nano-sheets, a first source/drain region disposed adjacent to the first gate line and contacting each of the first plurality of nano-sheets, a second source/drain region disposed adjacent to the second gate line and contacting each of the second plurality of nano-sheets, a first gate dielectric layer disposed between the first gate line and the first plurality of nano-sheets and between the first gate line and the vertical structure and including a stacked structure of a first interfacial dielectric layer and a first high-k layer, and a second gate dielectric layer disposed between the second gate line and the second plurality of nano-sheets and between the second gate line and the vertical structure, wherein the first gate line comprises a first main gate portion disposed on a top surface of the first nano-sheet stack and a first sub-gate portion disposed at a lower vertical level than each of the first plurality of nano-sheets, the second gate line comprises a second main gate portion disposed on a top surface of the second nano-sheet stack and a second sub-gate portion disposed at a lower vertical level than each of the second plurality of nano-sheets, the first gate dielectric layer includes a first portion disposed between the first gate line and the first plurality of nano-sheets, a second portion disposed between the first sub-gate portion and the vertical structure, and a third portion disposed between the first sub-gate portion and the first source/drain region, each of a thickness of the second portion of the first gate dielectric layer in the second horizontal direction and a thickness of the third portion of the first gate dielectric layer in the first horizontal direction is greater than the thickness of the first portion of the first gate dielectric layer in a vertical direction, the second gate dielectric layer includes a first portion disposed between the second gate line and the second plurality of nano-sheets, and a second portion disposed between the second sub-gate portion and the vertical structure, and a thickness of the second portion of the second gate dielectric layer in the second horizontal direction is greater than a thickness of the first portion of the second gate dielectric layer in the vertical direction.

### BRIEF DESCRIPTION OF THE DRAWINGS

Embodiments of the inventive concept will be more clearly understood from the following detailed description taken in conjunction with the accompanying drawings in which:

FIG. 1 is a schematic plan layout diagram of some components of an integrated circuit device according to embodiments;

FIG. 2A is a cross-sectional view taken along a line X1-X1′ of FIG. 1;

FIG. 2B is a cross-sectional view taken along a line Y1-Y1′ of FIG. 1;

FIG. 3A and FIG. 3B are enlarged cross-sectional views of a region EX1 of FIG. 2B;

FIG. 4 is a cross-sectional view of some components of an integrated circuit device according to an embodiment;

FIG. 5 is a cross-sectional view of some components of an integrated circuit device according to an embodiment;

FIG. 6, FIG. 7, FIG. 8, and FIG. 9 are cross-sectional views of some components of integrated circuit devices according to an embodiment;

FIG. 10A, FIG. 10B, FIG. 10C, FIG. 10D, and FIG. 10E are cross-sectional views for describing a method of manufacturing an integrated circuit device, according to embodiments; and

FIG. 11A, FIG. 11B, and FIG. 11C are cross-sectional views for describing a method of manufacturing an integrated circuit device, according to embodiments.

### DETAILED DESCRIPTION

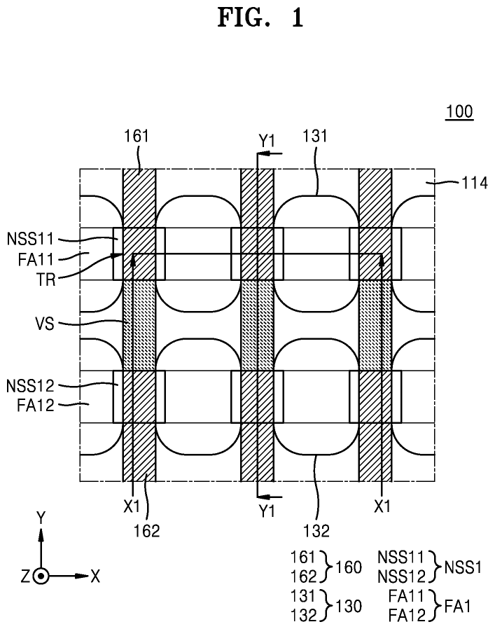

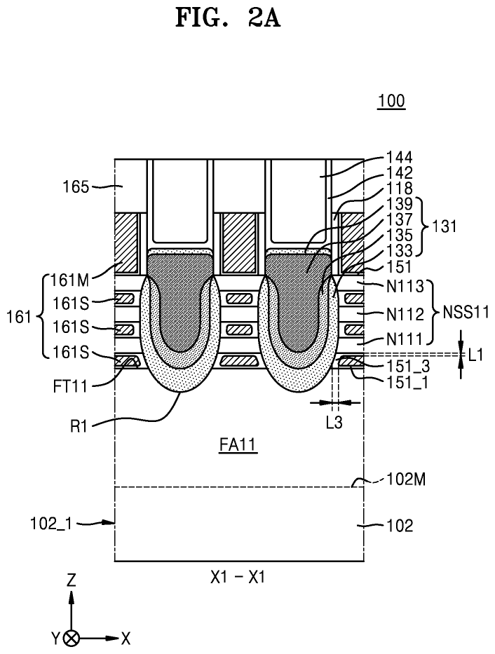

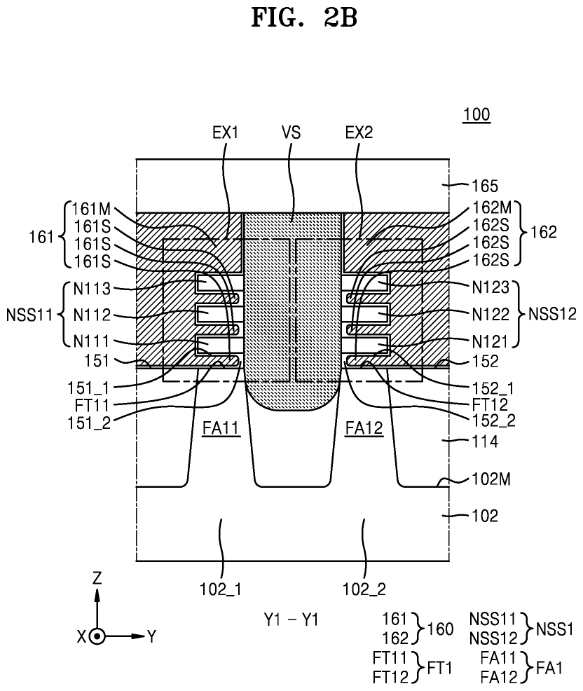

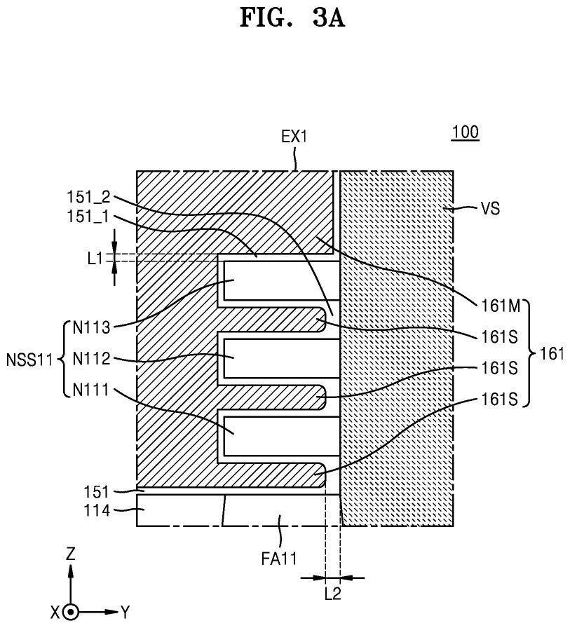

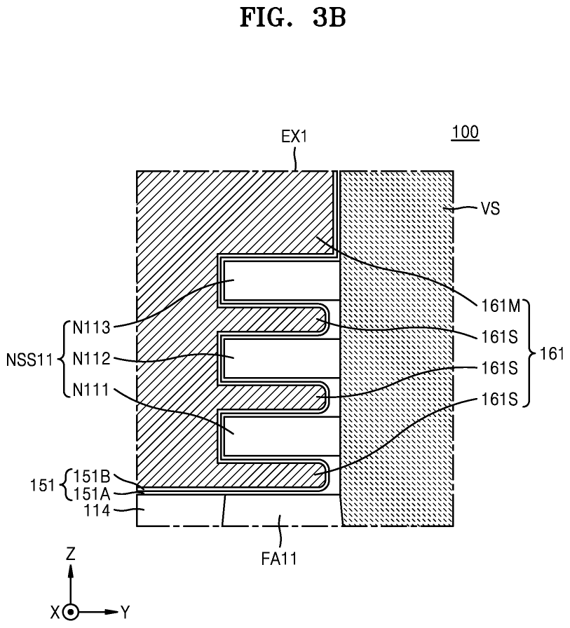

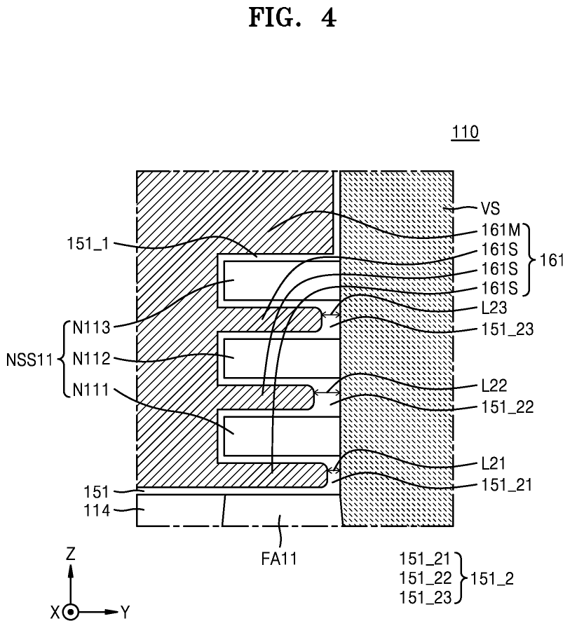

FIG. 1 is a schematic plan layout diagram of some components of an integrated circuit device 100 according to embodiments. FIG. 2A is a cross-sectional view taken along a line X1-X1′ of FIG. 1. FIG. 2B is a cross-sectional view taken along a line Y1-Y1′ of FIG. 1. FIG. 3A and FIG. 3B are enlarged cross-sectional views of a region EX1 of FIG. 2B, according to an embodiment.

Referring to FIG. 1, FIG. 2A, FIG. 2B, FIG. 3A, and FIG. 3B, the integrated circuit device 100 may include a field-effect transistor TR having a forksheet structure or a gate-all-around structure including an active region in the form of a nano-wire or a nano-sheet and a gate surrounding the active region.

Referring to FIG. 1, FIG. 2A, and FIG. 2B, the integrated circuit device 100 may include a plurality of fin-type active regions FA1 and a plurality of nano-sheet stacks NSS1. The plurality of fin-type active regions FA1 may protrude upward in a vertical direction (Z direction) from a substrate 102 and the plurality of nano-sheet stacks NSS1 may be arranged on the plurality of fin-type active regions FA1. The term “nano-sheet” as used herein refers to a conductive structure having a cross-section substantially perpendicular to a direction in which an electric current flows. It should be understood that the term “nano-sheet” as used herein may also include a nano-wire.

The substrate 102 may include a semiconductor like silicon (Si) or germanium (Ge) or a compound semiconductor like silicon germanium (SiGe), silicon carbide (SiC), gallium arsenide (GaAs), indium arsenide (InAs), indium gallium arsenide (InGaAs), or indium phosphorus oxide (InP). The terms SiGe, SiC, GaAs, InAS, InGaAs, and InP as used herein may refer to a material composed of elements included in each term and are not formulas representing stoichiometric relationships. The substrate 102 may include a first region 102_1 and a second region 1022 spaced apart from each other in a second horizontal direction (Y direction) crossing a first horizontal direction (X direction).

According to some embodiments, a first fin-type active region FA11 may be disposed on the first region 102_1 of the substrate 102. A second fin-type active region FA12 may be disposed on the second region 102_2 of the substrate 102. The first fin-type active region FA11 and the second fin-type active region FA12 may each extend in the first horizontal direction (X direction) and may be spaced apart from each other in the second horizontal direction (Y direction).

According to some embodiments, a device isolation layer 114 may cover both sidewalls of each of the plurality of fin-type active regions FA1 and may be disposed on the substrate 102. The device isolation layer 114 may include an oxide film, a nitride film, or a combination thereof.

According to some embodiments, a plurality of gate lines 160 may be arranged on the plurality of fin-type active regions FA1. The plurality of gate lines 160 may each extend in the second horizontal direction (Y direction).

In detail, the plurality of gate lines 160 may include a first gate line 161 and a second gate line 162 spaced apart from each other in the second horizontal direction (Y direction). The first gate line 161 may be disposed on the first fin-type active region FA11, on the first region 102_1 of the substrate 102. The second gate line 162 may be disposed on the second fin-type active region FA12, on the second region 102_2 of the substrate 102.

According to some embodiments, the plurality of nano-sheet stacks NSS1 may be arranged on fin top surfaces FT1 of the plurality of fin-type active regions FA1. The plurality of nano-sheet stacks NSS1 may be arranged in regions where the plurality of fin-type active regions FA1 and the plurality of gate lines 160 intersect each other.

In detail, the plurality of nano-sheet stacks NSS1 may include a first nano-sheet stack NSS11 and a second nano-sheet stack NSS12 spaced apart from each other in the second horizontal direction (Y direction). The first nano-sheet stack NSS11 may be disposed in a region where the first fin-type active region FA11 and the first gate line 161 intersect each other on the first region 102_1 of the substrate 102. The second nano-sheet stack NSS12 may be disposed in a region where the second fin-type active region FA12 and the second gate line 162 intersect each other on the second region 102_2 of the substrate 102.

According to some embodiments, a vertical structure VS may be disposed between the first gate line 161 and the second gate line 162. The vertical structure VS may be disposed between the first gate line 161 and the second gate line 162 in the second horizontal direction (Y direction). The vertical structure VS may have a top surface disposed at a same vertical level as top surfaces of the first gate line 161 and the second gate line 162. The vertical structure VS may include a portion disposed between the first fin-type active region FA11 and the second fin-type active region FA12. The device isolation layer 114 may be disposed under the vertical structure VS in a gap between the first fin-type active region FA11 and the second fin-type active region FA12. The device isolation layer 114 may be disposed under the vertical structure VS to completely fill the gap between the first fin-type active region FA11 and the second fin-type active region FA12. According to some embodiments, the vertical structure VS may include at least one of a silicon nitride (SiN), a silicon oxide (SiO), a silicon boron nitride (SiBN), a silicon oxide nitride (SiON), silicon oxycarbonitride (SiOCN), a silicon boron carbonitride (SiBCN), or a silicon oxycarbide (SiOC) material.

According to some embodiments, the vertical structure VS may contact each of the plurality of nano-sheet stacks NSS1. In detail, the vertical structure VS may contact the first nano-sheet stack NSS11 and the second nano-sheet stack NSS12, and may be disposed between the first nano-sheet stack NSS11 and the second nano-sheet stack NSS12. For example, the first nano-sheet stack NSS11 and the second nano-sheet stack NSS12 may be spaced apart from each other with the vertical structure VS disposed therebetween.

According to some embodiments, the plurality of nano-sheet stacks NSS1 may each include at least one nano-sheet facing a fin top surface FT1 at a position spaced apart from the fin top surface FT1 of a fin-type active region FA1 in the vertical direction (Z direction). In detail, the first nano-sheet stack NSS11 may include at least one nano-sheet facing a fin top surface FT11 at a position spaced apart from the fin top surface FT11 of a first fin-type active region FA11 in the vertical direction (Z direction). In detail, the second nano-sheet stack NSS12 may include at least one nano-sheet facing a fin top surface FT12 at a position spaced apart from the fin top surface FT12 of a second fin-type active region FA12 in the vertical direction (Z direction).

As shown in FIG. 2A and FIG. 2B, the first nano-sheet stack NSS11 may include a first nano-sheet N111, a second nano-sheet N112, and a third nano-sheet N113. The first nano-sheet N111, the second nano-sheet N112, and the third nano-sheet N113 may overlap each other in the vertical direction (Z direction) above the first fin-type active region FA11. The first nano-sheet N111, the second nano-sheet N112, and the third nano-sheet N113 may be positioned apart from the fin top surface FT11 of the first fin-type active region FA11 by different vertical distances (distances in the Z direction).

In the same regard, the second nano-sheet stack NSS12 may include a first nano-sheet N121, a second nano-sheet N122, and a third nano-sheet N123. The first nano-sheet N121, the second nano-sheet N122, and the third nano-sheet N123 may overlap each other in the vertical direction (Z direction) above the second fin-type active region FA12. The first nano-sheet N121, the second nano-sheet N122, and the third nano-sheet N123 may be positioned apart from the fin top surface FT12 of the second fin-type active region FA12 by different vertical distances (distances in the Z direction).

Although FIG. 2A and FIG. 2B show a case where each of the plurality of nano-sheet stacks NSS1 includes three nano-sheets, the inventive concept is not limited thereto, and each of the plurality of nano-sheet stacks NSS1 may include four or more nano-sheets or may include less than three nano-sheets.

Although FIG. 1 shows a case in which a planar shape of a nano-sheet stack NSS1 is substantially rectangular, the inventive concept is not limited thereto. The nano-sheet stack NSS1 may have various planar shapes according to planar shapes of the fin-type active regions FA1 and the gate lines 160. The present specification shows a configuration in which the plurality of nano-sheet stacks NSS1 and the plurality of gate lines 160 are arranged on a fin-type active region FA1, and the plurality of nano-sheet stacks NSS1 are arranged in a line in the first horizontal direction (X direction) on the one fin-type active region FA1. However, the number of nano-sheet stacks NSS1 and the number of gate lines 160 arranged on one fin-type active region FA1 are not particularly limited.

According to some embodiments, the first nano-sheet N111, the second nano-sheet N112, and the third nano-sheet N113 included in the first nano-sheet stack NSS11 may each be configured as a channel region. In the present specification, the first nano-sheet N111, the second nano-sheet N112, and the third nano-sheet N113 may each be referred to as a channel region. According to some embodiments, the first nano-sheet N111, the second nano-sheet N112, and the third nano-sheet N113 may each have a thickness within a range from about 4 nm to about 6 nm, but the inventive concept is not limited thereto. Here, the thickness of each of the first nano-sheet N111, the second nano-sheet N112, and the third nano-sheet N113 refers to a size in the vertical direction (Z direction). According to some embodiments, the first nano-sheet N111, the second nano-sheet N112, and the third nano-sheet N113 may have substantially a same thickness in the vertical direction (Z direction). According to some other embodiments, at least some of the first nano-sheet N111, the second nano-sheet N112, and the third nano-sheet N113 may have different thicknesses in the vertical direction (Z direction).

According to some embodiments, the same may be applied to the first nano-sheet N121, the second nano-sheet N122, and the third nano-sheet N123 included in the second nano-sheet stack NSS12. For example, the first nano-sheet N121, the second nano-sheet N122, and the third nano-sheet N123 may each be referred to as a channel region.

According to some embodiments, at least some of the first nano-sheet N111, the second nano-sheet N112, and the third nano-sheet N113 included in one first nano-sheet stack NSS11 may be different sizes in the first horizontal direction (X direction). According to some other embodiments, at least some of the first nano-sheet N111, the second nano-sheet N112, and the third nano-sheet N113 may have a same size in the first horizontal direction (X direction). According to some embodiments, the same may be applied to the first nano-sheet N121, the second nano-sheet N122, and the third nano-sheet N123 included in the second nano-sheet stack NSS12.

According to some embodiments, a plurality of nano-sheets may each contact the vertical structure VS. In detail, the first nano-sheet N111, the second nano-sheet N112, and the third nano-sheet N113 included in the first nano-sheet stack NSS11 may contact the vertical structure VS. In detail, the first nano-sheet N121, the second nano-sheet N122, and the third nano-sheet N123 included in the second nano-sheet stack NSS12 may contact the vertical structure VS.

In an example in which the vertical structure VS is disposed in contact with a plurality of nano-sheets, the plurality of gate lines 160 may not extend further in the second horizontal direction (Y direction) than the plurality of nano-sheets. In detail, in an example in which the vertical structure VS is disposed in contact with the first nano-sheet N111, the second nano-sheet N112, and the third nano-sheet N113 included in the first nano-sheet stack NSS11, the first gate line 161 may not extend further toward the second fin-type active region FA12 in the second horizontal direction (Y direction) than the first nano-sheet N111, the second nano-sheet N112, and the third nano-sheet N113 included in the first nano-sheet stack NSS11. In detail, in an example in which the vertical structure VS is disposed in contact with the first nano-sheet N121, the second nano-sheet N122, and the third nano-sheet N123 included in the second nano-sheet stack NSS12, the second gate line 162 may not extend further toward the first fin-type active region FA11 in the second horizontal direction (Y direction) than the first nano-sheet N121, the second nano-sheet N122, and the third nano-sheet N123 included in the second nano-sheet stack NSS12. According to some embodiments, a zero gate extension process may be applied to the integrated circuit device 100 shown in FIG. 1, FIG. 2A, and FIG. 2B.

As shown in FIG. 2A and FIG. 2B, the plurality of gate lines 160 may each include a main gate portion and a plurality of sub-gate portions. In detail, the first gate line 161 may include a first main gate portion 161M and a plurality of first sub-gate portions 161S. The first main gate portion 161M may extend in the second horizontal direction (Y direction) and overlap the first nano-sheet stack NSS11. In detail, the first main gate portion 161M may extend in the second horizontal direction (Y direction) while covering the top surface of the first nano-sheet stack NSS11. The plurality of first sub-gate portions 161S may be integrally connected to the first main gate portion 161M, and the plurality of first sub-gate portions 161S may be disposed between the first nano-sheet N111, the second nano-sheet N112, and the third nano-sheet N113 and between the first nano-sheet N111 and the first fin-type active region FA11. In detail, the plurality of first sub-gate portions 161S may be alternately disposed with the first fin-type active region FA11, the first nano-sheet N111, the second nano-sheet N112, and the third nano-sheet N113. In the vertical direction (Z direction), the thickness of each of the plurality of first sub-gate portions 161S may be less than the thickness of the first main gate portion 161M.

In the same regard, the second gate line 162 may include a second main gate portion 162M and a plurality of second sub-gate portions 162S. The second main gate portion 162M may extend in the second horizontal direction (Y direction) and overlap the second nano-sheet stack NSS12. In detail, the second main gate portion 162M may extend in the second horizontal direction (Y direction) while covering the top surface of the second nano-sheet stack NSS12. The plurality of second sub-gate portions 162S may be integrally connected to the second main gate portion 162M, and the plurality of second sub-gate portions 162S may each be disposed between the first nano-sheet N121, the second nano-sheet N122, and the third nano-sheet N123 and between the first nano-sheet N121 and the second fin-type active region FA12. In detail, the plurality of second sub-gate portions 162S may be alternately disposed with the second fin-type active region FA12, the first nano-sheet N121, the second nano-sheet N122, and the third nano-sheet N123. In the vertical direction (Z direction), the thickness of each of the plurality of second sub-gate portions 162S may be less than that of the second main gate portion 162M.

The plurality of gate lines 160 may each include a metal, a metal nitride, a metal carbide, or a combination thereof. The metal may be selected from among titanium (Ti), tungsten (W), ruthenium (Ru), niobium (Nb), molybdenum (Mo), hafnium (Hf), nickel (Ni), cobalt (Co), platinum (Pt), ytterbium (Yb), terbium (Tb), dysprosium (Dy), erbium (Er), or palladium (Pd). The metal nitride may be selected from titanium nitride (TiN) and tantalum nitride (TaN). The metal carbide may be TiAlC. However, the materials constituting the plurality of gate lines 160 are not limited to the examples herein.

Gate dielectric layers including a first gate dielectric layer 151 and a second gate dielectric layer 152 may be provided between the nano-sheet stack NSS1 and the gate line 160 and between the gate line 160 and the vertical structure VS. In detail, the first gate dielectric layer 151 may be disposed between the first nano-sheet stack NSS11 and the first gate line 161, and between the first gate line 161 and the vertical structure VS. For example, the first gate dielectric layer 151 may be disposed between each of the first nano-sheet N111, the second nano-sheet N112, and the third nano-sheet N113 included in the first nano-sheet stack NSS11 and the first gate line 161, between the first main gate portion 161M and the vertical structure VS, and between the plurality of first sub-gate portions 161S and the vertical structure VS. In detail, the second gate dielectric layer 152 may be disposed between the second nano-sheet stack NSS12 and the second gate line 162, and between the second gate line 162 and the vertical structure VS. For example, the second gate dielectric layer 152 may be disposed between each of the first nano-sheet N121, the second nano-sheet N122, and the third nano-sheet N123 included in the second nano-sheet stack NSS12 and the second gate line 162, between the second main gate portion 162M and the vertical structure VS, and between the plurality of second sub-gate portions 162S and the vertical structure VS.

According to some embodiments, a pair of source/drain regions 130 may be arranged on sides of the gate line 160 with a gate line 160 disposed therebetween, on the fin-type active region FA1. In detail, a pair of first source/drain regions 131 may be arranged on opposite sides of the first gate line 161 with the first gate line 161 disposed therebetween, on the first fin-type active region FA11. A first source/drain region 131 may be disposed on the first fin-type active region FA11 between a pair of first nano-sheet stacks NSS11 adjacent to each other. The first source/drain region 131 may contact sidewalls of the first nano-sheet stack NSS11 surrounded by the first gate line 161 adjacent thereto. In the same regard, a pair of second source/drain regions 132 may be arranged on opposite sides of the second gate line 162 with the second gate line 162 disposed therebetween, on the second fin-type active region FA12. A second source/drain region 132 may be disposed on the second fin-type active region FA12 between a pair of second nano-sheet stacks NSS12 adjacent to each other. The second source/drain region 132 may contact sidewalls of the second nano-sheet stack NSS12 surrounded by the second gate line 162 adjacent thereto.

According to some embodiments, sidewalls of each of the plurality of gate lines 160 may be covered by an outer insulation spacer 118. In detail, opposite sidewalls of each of first gate lines 161 may be covered by the outer insulation spacer 118. The outer insulation spacer 118 may cover the sidewalls of the first main gate portion 161M on the top surface of the first nano-sheet stack NSS11. The outer insulation spacer 118 may be spaced apart from the first gate line 161 with the first gate dielectric layer 151 disposed therebetween. The outer insulation spacer 118 may include SiN, SiO, silicon carbonitride (SiCN), silicon boron nitride (SiBN), silicon oxynitride (SiON), silicon oxycarbonitride (SiOCN), silicon boron carbon nitride (SiBCN), silicon oxycarbide (SiOC), or a combination thereof. The terms SiN, SiO, SiCN, SiBN, SiON, SiOCN, SiBCN, and SiOC as used herein refer to materials composed of elements included in each term and are not formulas representing stoichiometric relationships. Although not shown, the same may be applied to the second gate line 162.

According to some embodiments, the plurality of source/drain regions 130 may each include a portion overlapping the outer insulation spacer 118 in the vertical direction (Z direction). For example, the first source/drain regions 131 may each include a portion overlapping the outer insulation spacer 118 in the vertical direction (Z direction). According to some embodiments, the plurality of source/drain regions 130 may each be spaced apart from a main gate portion in the vertical direction (Z direction). For example, the first source/drain regions 131 may each be spaced apart from the first main gate portion 161M in the vertical direction (Z direction). Although not shown, the same may be applied to the second source/drain region 132.

According to some embodiments, sidewalls of each of a plurality of sub-gate portions may be spaced apart from the source/drain region 130 with a gate dielectric layer disposed therebetween. For example, opposite sidewalls of each of the plurality of first sub-gate portions 161S may be spaced apart from the first source/drain region 131 with the first gate dielectric layer 151 disposed therebetween. A gate dielectric layer may include a portion contacting a first semiconductor layer of the source/drain region 130. For example, the first gate dielectric layer 151 may include a portion contacting a first semiconductor layer 133 of the first source/drain region 131. Although not shown, the same may be applied to the second source/drain region 132.

According to some embodiments, a plurality of recesses R1 may be formed on the fin-type active region FA1. The vertical level of a lowermost surface of each of the plurality of recesses R1 may be lower than the vertical level of the fin top surface FT1 of the fin-type active region FA1.

According to some embodiments, the plurality of source/drain regions 130 may be arranged in the plurality of recesses R1. In detail, each source/drain region of the plurality of source/drain regions 130 may be disposed adjacent to at least one first gate line 161 selected from among the plurality of first gate lines 161. Each source/drain region of plurality of first source/drain regions 131 may have a sidewall facing the first nano-sheet N111, the second nano-sheet N112, and the third nano-sheet N113 included in the first nano-sheet stack NSS11 adjacent thereto. Each source/drain region of plurality of first source/drain regions 131 may contact the first nano-sheet N111, the second nano-sheet N112, and the third nano-sheet N113 included in the first nano-sheet stack NSS11 adjacent thereto. The plurality of first source/drain regions 131 may have bottom surfaces contacting a plurality of first fin-type active regions FA11. Although not shown, the same may be applied to the second source/drain regions 132.

According to some embodiments, the plurality of source/drain regions 130 may include a plurality of semiconductor layers. In detail, a plurality of semiconductor layers included in the first source/drain region 131 may include the first semiconductor layer 133, a second semiconductor layer 135 formed on the first semiconductor layer 133, and a third semiconductor layer 137 formed on the second semiconductor layer 135. The first semiconductor layer 133 may be disposed in the recess R1, the second semiconductor layer 135 may be disposed on the first semiconductor layer 133, and the third semiconductor layer 137 may be disposed on the second semiconductor layer 135. An upper surface of the third semiconductor layer 137 may be higher than a top surface of the third nano-sheet N113 in the vertical direction (Z direction). According to some embodiments, the plurality of semiconductor layers may further include a capping layer 139 formed on the third semiconductor layer 137. Although not shown, the same may be applied to the second source/drain regions 132.

According to some embodiments, in each of the plurality of first source/drain regions 131, the first semiconductor layer 133 may include a portion contacting a channel region and a portion contacting the first fin-type active region FA11. In other words, the first semiconductor layer 133 may include a portion contacting the first nano-sheet N111, the second nano-sheet N112, and the third nano-sheet N113, a portion contacting the plurality of first sub-gate portions 161S, and a portion contacting the first fin-type active region FA11. Although not shown, the same may be applied to the second source/drain regions 132.

According to some embodiments, a capping insulation pattern 165 may be disposed on top surfaces of the first gate dielectric layer 151, the second gate dielectric layer 152, the gate line 160, and the outer insulation spacer 118. In detail, the top surfaces of the first gate dielectric layer 151, the second gate dielectric layer 152, the gate line 160, and the outer insulation spacer 118 may be covered by a capping insulation pattern 165. The capping insulation pattern 165 may include a silicon nitride layer.

According to some embodiments, an insulation liner 142 may be disposed on a plurality of outer insulation spacers 118 and the plurality of source/drain regions 130. In detail, the plurality of outer insulation spacers 118 and the plurality of source/drain regions 130 may be covered by the insulation liner 142. The insulation liner 142 may include SiN, SiO, SiCN, SiBN, SiON, SiOCN, SiBCN, SiOC, or a combination thereof. According to some embodiments, the insulation liner 142 may be omitted. An inter-gate insulation layer 144 may be disposed on the insulation liner 142. The inter-gate insulation layer 144 may include a silicon nitride layer, a silicon oxide layer, a SiON layer, a SiOCN layer, or a combination thereof. When the insulation liner 142 is omitted, the inter-gate insulation layer 144 may contact the plurality of source/drain regions 130.

As shown in FIG. 1, a plurality of field effect transistors TR may be formed on the substrate 102 at portions where the plurality of fin-type active regions FA1 and the plurality of gate lines 160 intersect each other. The plurality of field effect transistors TR may constitute, for example, a logic circuit or a memory device.

Referring to FIG. 3A, the integrated circuit device 100 may include the first gate dielectric layer 151 disposed between the first nano-sheet stack NSS11 and the first gate line 161 and between the first gate line 161 and the vertical structure VS on the first region 102_1 of the substrate 102.

According to some embodiments, the first gate dielectric layer 151 may include a first portion 151_1 disposed between the first gate line 161 and the first nano-sheet stack NSS11 and a second portion 151_2 disposed between the plurality of first sub-gate portions 161S and the vertical structure VS. In detail, the first portion 151_1 of the first gate dielectric layer 151 may be disposed between the first gate line 161 and the first nano-sheet N111, the second nano-sheet N112, and the third nano-sheet N113 included in the first nano-sheet stack NSS11. In detail, the second portion 151_2 of the first gate dielectric layer 151 may be integrally connected to the first portion 151_1 and may be disposed on the sidewall of the vertical structure VS between the first nano-sheet N111, the second nano-sheet N112, and the third nano-sheet N113 and between the first nano-sheet N111 and the first fin-type active region FA11. For example, the second portion 151_2 of the first gate dielectric layer 151 may overlap the plurality of first sub-gate portions 161S and the vertical structure VS in the second horizontal direction (Y direction) between the plurality of first sub-gate portions 161S and the vertical structure VS.

According to some embodiments, the first gate dielectric layer 151 may be further disposed between the first main gate portion 161M and a sidewall of the vertical structure VS. Also, the first gate dielectric layer 151 may be further disposed between the first gate line 161 and the fin top surface FT11 of the first fin-type active region FA11 and between the first gate line 161 and the device isolation layer 114. A portion of the first gate dielectric layer 151 disposed between the first gate line 161 and the fin top surface FT11 of the first fin-type active region FA11 and between the first gate line 161 and the device isolation layer 114 may extend in the second horizontal direction (Y direction).

According to some embodiments, a thickness L2 of the second portion 151_2 of the first gate dielectric layer 151 in the second horizontal direction (Y direction) may be greater than a thickness L1 of the first portion 151_1 of the first gate dielectric layer 151 in the vertical direction (Z direction). According to some embodiments, a thickness L2 of the second portion 151_2 of the first gate dielectric layer 151 in the second horizontal direction (Y direction) may be greater than a thickness of the first portion 151_1 of the first gate dielectric layer 151 in the second horizontal direction (Y direction).

According to some embodiments, a thickness of the first gate dielectric layer 151 disposed between the first main gate portion 161M and the sidewall of the vertical structure VS in the second horizontal direction (Y direction) may be about the same as the thickness L1 of the first portion 151_1 of the first gate dielectric layer 151 in the vertical direction (Z direction).

According to some embodiments, the thickness L2 of the second portion 151_2 of the first gate dielectric layer 151 in the second horizontal direction (Y direction) may be greater than a thickness in the second horizontal direction (Y direction) of a portion of the first gate dielectric layer 151 disposed between the first main gate portion 161M and a sidewall of the vertical structure VS.

According to some embodiments, the thickness L2 of the second portion 151_2 of the first gate dielectric layer 151 in the second horizontal direction (Y direction) may increase toward the first portion 151_1 of the first gate dielectric layer 151 adjacent thereto. In detail, the first sub-gate portions 161S may have rounded end portions adjacent to the sidewall of the vertical structure VS and the thickness L2 of the second portion 151_2 of the first gate dielectric layer 151 in the second horizontal direction (Y direction) may increase toward the first portion 151_1 adjacent thereto. In detail, the thickness L2 of the second portion 151_2 of the first gate dielectric layer 151 in the second horizontal direction (Y direction) may increase toward a nano-sheet adjacent thereto. For example, the thickness L2 of the second portion 151_2 of the first gate dielectric layer 151 in the second horizontal direction (Y direction) disposed between the third nano-sheet N113 and the second nano-sheet N112 may increase toward the third nano-sheet N113 and may increase toward the second nano-sheet N112. The thickness L2 of the second portion 151_2 of the first gate dielectric layer 151 in the second horizontal direction (Y direction) disposed between the third nano-sheet N113 and the second nano-sheet N112 may have the smallest value at a vertical level at which a distance to the third nano-sheet N113 and a distance to the second nano-sheet N112 are the same.

In the same regard, as shown in FIG. 2B, the integrated circuit device 100 may include the second gate dielectric layer 152 disposed between the second nano-sheet stack NSS12 and the second gate line 162 and between the second gate line 162 and the vertical structure VS on the second region 102_2 of the substrate 102.

According to some embodiments, the second gate dielectric layer 152 may include a first portion 152_1 disposed between the second gate line 162 and the second nano-sheet stack NSS12 and a second portion 1522 disposed between the plurality of second sub-gate portions 162S and the vertical structure VS. In detail, the first portion 152_1 of the second gate dielectric layer 152 may be disposed between the second gate line 162 and the first nano-sheet N121, the second nano-sheet N122, and the third nano-sheet N123 included in the second nano-sheet stack NSS12. In detail, the second portion 152_2 of the second gate dielectric layer 152 may be integrally connected to the first portion 152_1 and may be disposed on the sidewall of the vertical structure VS between the first nano-sheet N121, the second nano-sheet N122, and the third nano-sheet N123 and between the first nano-sheet N121 and the second fin-type active region FA12. For example, the second portion 152_2 of the second gate dielectric layer 152 may overlap the plurality of second sub-gate portions 162S and the vertical structure VS in the second horizontal direction (Y direction) between the plurality of second sub-gate portions 162S and the vertical structure VS.

The second gate dielectric layer 152 may be further disposed between the second main gate portion 162M and a sidewall of the vertical structure VS in the vertical direction (Z direction). Also, the second gate dielectric layer 152 may be further disposed between the second gate line 162 and the fin top surface FT12 of the second fin-type active region FA12 and between the second gate line 162 and the device isolation layer 114. A portion of the second gate dielectric layer 152 disposed between the second gate line 162 and the fin top surface FT12 of the first fin-type active region FA11 and between the second gate line 162 and the device isolation layer 114 may extend in the second horizontal direction (Y direction).

According to some embodiments, a thickness of the second portion 152_2 of the second gate dielectric layer 152 in the second horizontal direction (Y direction) may be greater than a thickness of the first portion 152_1 of the second gate dielectric layer 152 in the vertical direction (Z direction). According to some embodiments, the thickness of the second portion 152_2 of the second gate dielectric layer 152 in the second horizontal direction (Y direction) may be greater than a thickness of the first portion 152_1 of the second gate dielectric layer 152 in the second horizontal direction (Y direction).

According to some embodiments, the thickness of the second portion 152_2 of the second gate dielectric layer 152 in the second horizontal direction (Y direction) may be greater than a thickness in the second horizontal direction (Y direction) of a portion of the second gate dielectric layer 152 disposed between the second main gate portion 162M and a sidewall of the vertical structure VS.

According to some embodiments, the thickness the second portion 152_2 of the second gate dielectric layer 152 in the second horizontal direction (Y direction) may increase toward the first portion 152_1 of the second gate dielectric layer 152 adjacent thereto. In detail, the second sub-gate portions 162S may have rounded end portions adjacent to the sidewall of the vertical structure VS and the thickness of the second portion 152_2 of the second gate dielectric layer 152 in the second horizontal direction (Y direction) may increase toward the first portion 152_1 of the second gate dielectric layer 152 adjacent thereto.

In an example in which the integrated circuit device 100 according to the inventive concept includes the first gate dielectric layer 151, in which the second portion 1512 disposed on the sidewall of the vertical structure VS between the first nano-sheet N111, the second nano-sheet N112, and the third nano-sheet N113 included in the first nano-sheet stack NSS11 and between first nano-sheet N111 and the first fin-type active region FA11 has a thickness greater than a thickness of the first portion 151_1 disposed between the first gate line 161 and the first nano-sheet N111, a gate area at which the second portion 1512 is disposed may be decreased, and thus capacitance of the integrated circuit device 100 may be decreased.

In the same regard, in an example in which the integrated circuit device 100 according to the inventive concept includes the second gate dielectric layer 152, in which the second portion 152_2 disposed on the sidewall of the vertical structure VS between the first nano-sheet N121, the second nano-sheet N122, and the third nano-sheet N123 included in the second nano-sheet stack NSS12 and between first nano-sheet N121 and the second fin-type active region FA12 has a thickness greater than a thickness of the first portion 1521 disposed between the second gate line 162 and the first nano-sheet N121, a gate area at which the second portion 152_2 is disposed may be decreased, and thus capacitance of the integrated circuit device 100 may be decreased.

In other words, the integrated circuit device 100 including a transistor exhibiting an improved capacitance reduction effect may be provided according to the inventive concept. In other words, the integrated circuit device 100 with improved performance and reliability may be provided according to the inventive concept.

According to some embodiments, as shown in FIG. 2A, the first gate dielectric layer 151 may further include a third portion 151_3 disposed between the plurality of first sub-gate portions 161S and the first source/drain region 131. In detail, the third portion 151_3 of the first gate dielectric layer 151 may be integrally connected to the first portion 151_1 and may be disposed on the sidewall of the first source/drain region 131 between the first nano-sheet N111, the second nano-sheet N112, and the third nano-sheet N113, and between the first nano-sheet N111 and the first fin-type active region FA11. For example, the third portion 151_3 of the first gate dielectric layer 151 may overlap the plurality of first sub-gate portions 161S and the first source/drain region 131 in the first horizontal direction (X direction) between the plurality of first sub-gate portions 161S and the first source/drain region 131.

According to some embodiments, a thickness L3 of the third portion 151_3 of the first gate dielectric layer 151 in the first horizontal direction (X direction) may be greater than the thickness L1 of the first portion 151_1 of the first gate dielectric layer 151 in the vertical direction (Z direction). According to some embodiments, the thickness L3 of the third portion 151_3 of the first gate dielectric layer 151 in the first horizontal direction (X direction) may be greater than the thickness of the first portion 151_1 of the first gate dielectric layer 151 in the first horizontal direction (X direction).

Referring to FIG. 3B, a gate dielectric layer may include a stacked structure of an interfacial dielectric layer and a high-k layer. In detail, the first gate dielectric layer 151 may include a stacked structure of a first interfacial dielectric layer 151A and a first high-k layer 151B. In detail, the first gate dielectric layer 151 may be formed as a stacked structure of the first interfacial dielectric layer 151A and the first high-k layer 151B in which the first high-k layer 151B may be disposed on the first gate line 161 and the first interfacial dielectric layer 151A may be disposed on the first high-k layer 151B, but the stacked structure is not limited thereto. The first interfacial dielectric layer 151A may include a low-k material layer having a dielectric constant of about 9 or less, and may be formed of, for example, a silicon oxide layer, a silicon oxynitride layer, or a combination thereof. According to some embodiments, the first interfacial dielectric layer 151A may be omitted. The first high-k layer 151B may include a material having a higher dielectric constant than that of a silicon oxide layer. For example, the first high-k layer 151B may have a dielectric constant from about 10 to about 25. The first high-k layer 151B may include hafnium oxide but is not limited thereto. In the same regard, the second gate dielectric layer 152 may include a stacked structure of a second interfacial dielectric layer and a second high-k layer.

FIG. 4 is a cross-sectional view of some of components of an integrated circuit device 110 according to an embodiment. In detail, FIG. 4 is an enlarged cross-sectional view of a region EX1 of FIG. 2B. Descriptions below focus on differences from the integrated circuit device 100 described with reference to FIG. 1, FIG. 2A, FIG. 2B, FIG. 3A, and FIG. 3B.

Referring to FIG. 4, the second portion 151_2 of the first gate dielectric layer 151 may include a plurality of sub-portions arranged between the first nano-sheet N111, the second nano-sheet N112, and the third nano-sheet N113, and between the first nano-sheet N111 and the first fin-type active region FA11. In detail, a first sub-portion 151_21 of the second portion 151_2 may be disposed between the first fin-type active region FA11 and the first nano-sheet N111. In detail, a second sub-portion 151_22 of the second portion 1512 may be disposed between the first nano-sheet N111 and the second nano-sheet N112. In detail, a third sub-portion 151_23 of the second portion 151_2 may be disposed between the second nano-sheet N112 and the third nano-sheet N113.

According to some embodiments, the plurality of sub-portions of the second portion 151_2 may have a same thickness or different thicknesses in the second horizontal direction (Y direction). For example, in an example in which the plurality of sub-portions of the second portion 151_2 have different thicknesses in the second horizontal direction (Y direction), the plurality of first sub-gate portions 161S may each have different lengths in the second horizontal direction (Y direction). In detail, thicknesses of the first sub-portion 151_21, the second sub-portion 151_22, and the third nano-sheet N113 of the second portion 151_2 in the second horizontal direction (Y direction) may be different from one another. For example, a thickness L22 of the second sub-portion 151_22 of the second portion 151_2 in the second horizontal direction (Y direction) may be greater than a thickness L21 of the first sub-portion 151_21 of the second portion 151_2 in the second horizontal direction (Y direction) and a thickness L23 of the third sub-portion 151_23 of the second portion 151_2 in the second horizontal direction (Y direction). For example, the thickness L23 of the third sub-portion 151_23 of the second portion 151_2 in the second horizontal direction (Y direction) may be greater than the thickness L21 of the first sub-portion 151_21 of the second portion 151_2 in the second horizontal direction (Y direction).

According to some other embodiments, unlike the structure shown in the drawing, a thickness of the second sub-portion 151_22 of the second portion 151_2 in the second horizontal direction (Y direction) may be less than a thickness of the first sub-portion 151_21 of the second portion 151_2 in the second horizontal direction (Y direction) and/or a thickness of the third sub-portion 151_23 of the second portion 151_2 in the second horizontal direction (Y direction). According to some other embodiments, unlike the structure shown in the drawing, a thickness of the third sub-portion 151_23 of the second portion 151_2 in the second horizontal direction (Y direction) may be less than a thickness of the first sub-portion 151_21 of the second portion 151_2 in the second horizontal direction (Y direction).

According to some other embodiments, unlike the structure shown in the drawing, some of the plurality of sub-portions of the second portion 151_2 may have substantially the same thickness in the second horizontal direction (Y direction). For example, a thickness of the third sub-portion 151_23 of the second portion 151_2 in the second horizontal direction (Y direction) may be substantially the same as a thickness of the first sub-portion 151_21 of the second portion 151_2 in the second horizontal direction (Y direction).

The second portion 151_2 of the first gate dielectric layer 151 of the integrated circuit device 110 according to the inventive concept may include a plurality of sub-portions having different thicknesses. For example, the thicknesses of the plurality of sub-portions of the second portion 151_2 of the first gate dielectric layer 151 may be adjusted individually.

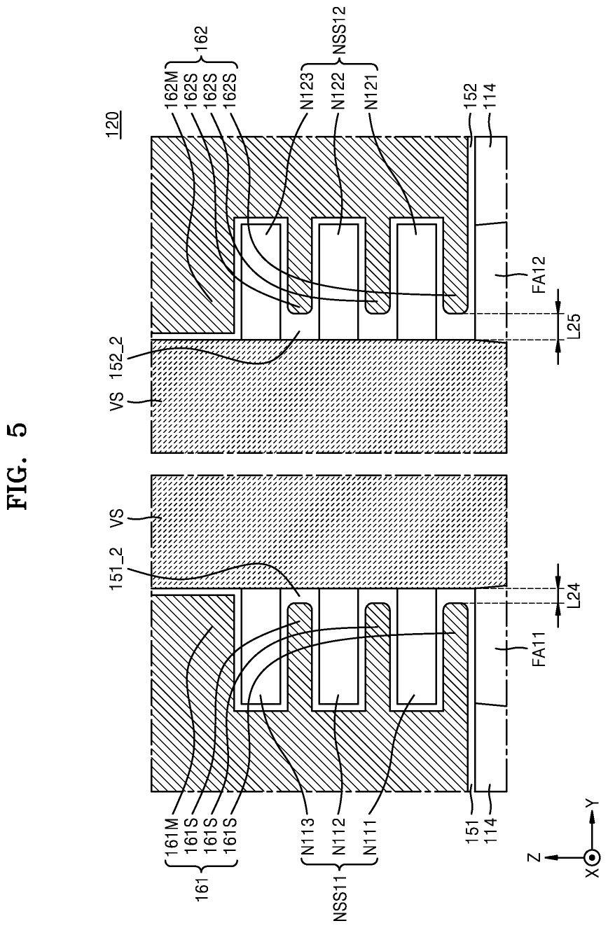

FIG. 5 is a cross-sectional view of some of components of an integrated circuit 120 device according to an embodiment. In detail, FIG. 5 is an enlarged cross-sectional view of the region EX1 and a region EX2 of FIG. 2B. Descriptions below focus on differences from the integrated circuit device 100 described with reference to FIG. 1, FIG. 2A, FIG. 2B, FIG. 3A, and FIG. 3B.

Referring to FIG. 5, a thickness L24 of the second portion 151_2 of the first gate dielectric layer 151 in the second horizontal direction (Y direction) may be different from a thickness L25 of the second portion 152_2 of the second gate dielectric layer 152 in the second horizontal direction (Y direction).

According to some embodiments, the thickness L25 of the second portion 152_2 of the second gate dielectric layer 152 in the second horizontal direction (Y direction) may be greater than the thickness L24 of the second portion 152_2 of the first gate dielectric layer 151 in the second horizontal direction (Y direction). According to some other embodiments, unlike the structure shown in the drawing, the thickness L24 of the second portion 151_2 of the first gate dielectric layer 151 in the second horizontal direction (Y direction) may be greater than the thickness L25 of the second portion 152_2 of the second gate dielectric layer 152 in the second horizontal direction (Y direction).

The second portion 152_2 of the second gate dielectric layer 152 of the integrated circuit device 110 according to the inventive concept may have a thickness configured as needed. In other words, the second portion 152_2 of the second gate dielectric layer 152 may be adjusted to have a thickness different from that of the second portion 151_2 of the first gate dielectric layer 151.

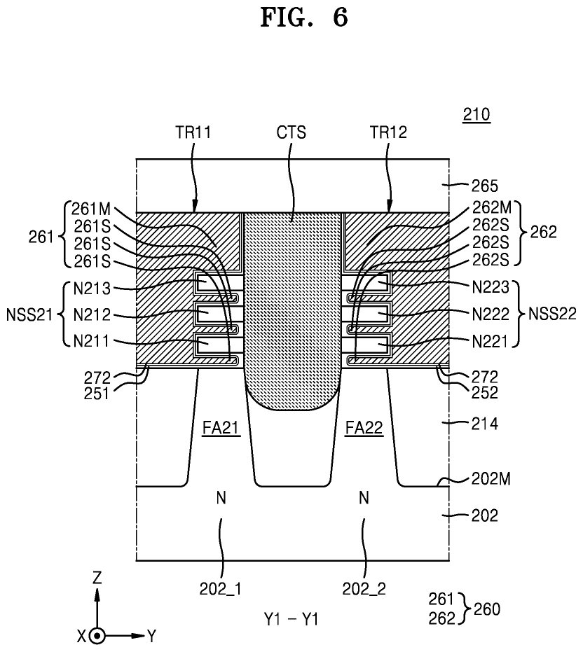

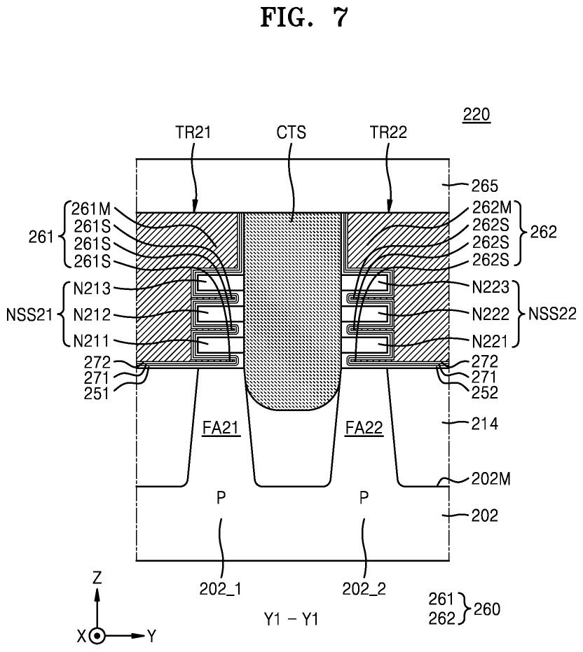

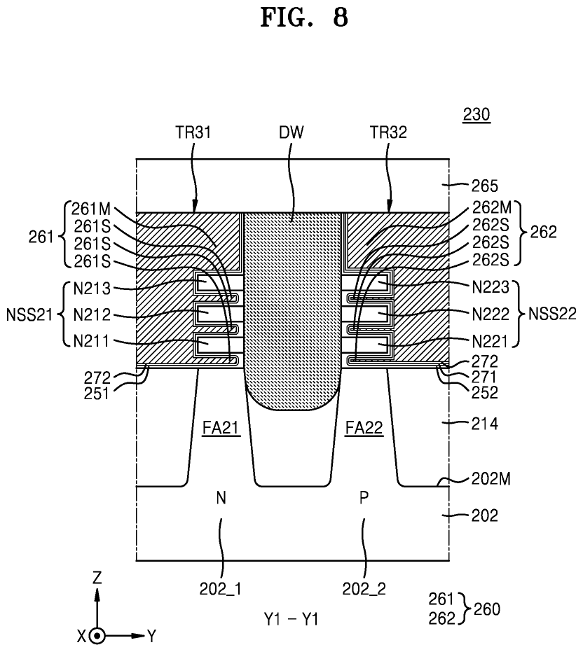

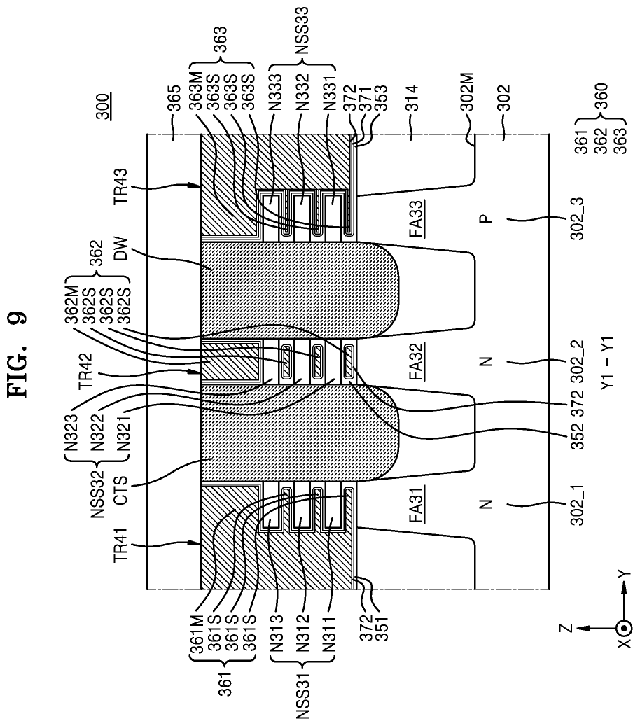

FIG. 6, FIG. 7, FIG. 8, and FIG. 9 are cross-sectional views of some of components of integrated circuit devices 210, 220, 230, and 300 according to an embodiment.

Referring to FIG. 6, an integrated circuit device 210 includes a first fin-type active region FA21 extending in the first horizontal direction (X direction) on a first region 202_1 of a substrate 202 and a second fin-type active region FA22 extending in a first horizontal direction (X direction) on a second region 202_2 of the substrate 202 and apart from the first fin-type active region FA21 in the second horizontal direction (Y direction).

According to some embodiments, a first gate line 261 may be disposed on the first fin-type active region FA21 and a second gate line 262 may be disposed on the second fin-type active region FA22. The first gate line 261 and the second gate line 262 may extend in the second horizontal direction (Y direction). The first gate line 261 and the second gate line 262 may be spaced apart from each other in the second horizontal direction (Y direction) with a cutting structure CTS disposed therebetween.

According to some embodiments, the cutting structure CTS may be a type of the vertical structure VS described herein with reference to FIG. 1, FIG. 2A, FIG. 2B, FIG. 3A, and FIG. 3B. In detail, the vertical structure VS disposed between the first region 202_1 and the second region 202_2 of the integrated circuit device 210, which are doped with the same conductivity type, may be referred to as the cutting structure CTS.

According to some embodiments, a first nano-sheet stack NSS21 may be disposed on a fin top surface of the first fin-type active region FA21. The first nano-sheet stack NSS21 may include a first plurality of nano-sheets surrounded by the first gate line 261.

According to some embodiments, a second nano-sheet stack NSS22 may be disposed on a fin top surface of the second fin-type active region FA22. The second nano-sheet stack NSS22 may include a second plurality of nano-sheets surrounded by the second gate line 262.

According to some embodiments, the first nano-sheet stack NSS21 and the second nano-sheet stack NSS22 may be spaced apart from each other in the second horizontal direction (Y direction) with the cutting structure CTS disposed therebetween. Descriptions of the integrated circuit device 100 given herein may be referred to for the first nano-sheet stack NSS21 including the first plurality of nano-sheets included therein, and the second nano-sheet stack NSS22 including the second plurality of nano-sheets included therein.

According to some embodiments, the cutting structure CTS may be disposed between the first gate line 261 and the second gate line 262. The cutting structure CTS may include an insulation material. For example, the cutting structure CTS may include silicon nitride, silicon oxide, and/or silicon oxynitride. According to some embodiments, the cutting structure CTS may be disposed in contact with the first plurality of nano-sheets including a first nano-sheet N211, a second nano-sheet N212, and a third nano-sheet N213 included in the first nano-sheet stack NSS21 and may be disposed in contact with the second plurality of nano-sheets including a first nano-sheet N221, a second nano-sheet N222, and a third nano-sheet N223 included in the second nano-sheet stack NSS22.

According to some embodiments, the first region 202_1 and the second region 202_2 of the integrated circuit device 210 may be doped with the same conductivity type. For example, both the first region 202_1 and the second region 202_2 of the integrated circuit device 210 may be n-type field effect transistor (nFET) regions. In other words, both a transistor TR11 formed on a portion of the first region 202_1 of the integrated circuit device 210 at which the first fin-type active region FA21 and the first gate line 261 intersect each other, and a transistor TR12 formed on a portion of the second region 202_2 of the integrated circuit device 210 at which the second fin-type active region FA22 and the second gate line 262 intersect each other, may be nFETs.

According to some embodiments, the first gate line 261 may include a first main gate portion 261M on the top surface of the first nano-sheet stack NSS21. According to some embodiments, a plurality of first sub-gate portions 261S may be integrally connected to the first main gate portion 261M and arranged at a vertical level lower than those of the first plurality of nano-sheets. In the same regard, the second gate line 262 may include a second main gate portion 262M on the top surface of the second nano-sheet stack NSS22. According to some embodiments, a plurality of second sub-gate portions 262S may be integrally connected to the second main gate portion 262M and arranged at a vertical level lower than those of the second plurality of nano-sheets.

According to some embodiments, a first gate dielectric layer 251 may be disposed between the first nano-sheet stack NSS21 and the first gate line 261 on the first region 202_1 of the substrate 202, and between the first gate line 261 and the cutting structure CTS. In the same regard, a second gate dielectric layer 252 may be disposed between the second nano-sheet stack NSS22 and the second gate line 262 on the second region 202_2 of the substrate 202, and between the second gate line 262 and the cutting structure CTS.

According to some embodiments, the first gate dielectric layer 251 may include a first portion disposed between the first gate line 261 and the first nano-sheet stack NSS21 and a second portion disposed between the plurality of first sub-gate portions 261S and the cutting structure CTS. According to some embodiments, a thickness of the second portion in the second horizontal direction (Y direction) may be greater than a thickness of the first portion in the vertical direction (Z direction). Further, a thickness of the second portion in the second horizontal direction (Y direction) may be greater than a thickness of the first portion in the second horizontal direction (Y direction).

According to some embodiments, the second gate dielectric layer 252 may include a first portion disposed between the second gate line 262 and the second nano-sheet stack NSS22 and a second portion disposed between the plurality of second sub-gate portions 262S and the cutting structure CTS. According to some embodiments, a thickness of the second portion in the second horizontal direction (Y direction) may be greater than a thickness of the first portion in the vertical direction (Z direction). Further, a thickness of the second portion in the second horizontal direction (Y direction) may be greater than a thickness of the first portion in the second horizontal direction (Y direction).

According to some embodiments, a second metal layer 272 may be disposed on the first gate dielectric layer 251 and the second gate dielectric layer 252. The second metal layer 272 may be disposed between the first gate dielectric layer 251 and the first gate line 261, and between the second gate dielectric layer 252 and the second gate line 262. According to some embodiments, the second metal layer 272 may include a metal for forming an nFET.

Referring to FIG. 7, descriptions below focus on the differences from the integrated circuit device 210 described herein with reference to FIG. 6.

According to some embodiments, the first region 202_1 and the second region 202_2 of an integrated circuit device 220 may be doped with the same conductivity type. For example, both the first region 202_1 and the second region 202_2 of the integrated circuit device 220 may be p-type field effect transistor (pFET) regions. For example, both a transistor TR21 formed on a portion of the first region 202_1 of the integrated circuit device 220 at which the first fin-type active region FA21 and the first gate line 261 intersect each other, and a transistor TR22 formed on a portion of the second region 202_2 of the integrated circuit device 220 at which the second fin-type active region FA22 and the second gate line 262 intersect each other, may be pFETs.

According to some embodiments, a first metal layer 271 and the second metal layer 272 may be arranged on the first gate dielectric layer 251 and the second gate dielectric layer 252. For example, the first metal layer 271 may be disposed on the first gate dielectric layer 251 and the second metal layer 272 may be disposed on the first metal layer 271. The first metal layer 271 and the second metal layer 272 may be arranged between the first gate dielectric layer 251 and the first gate line 261, and between the second gate dielectric layer 252 and the second gate line 262. In detail, the second metal layer 272 may be spaced apart from the first gate dielectric layer 251 and the second gate dielectric layer 252 with the first metal layer 271 disposed therebetween. According to some embodiments, the first metal layer 271 may include a metal for forming a pFET. According to some other embodiments, unlike the structure shown in the drawing, the integrated circuit device 220 may include the first metal layer 271 on the first gate dielectric layer 251 and the second gate dielectric layer 252 and may not include the second metal layer 272 on the first metal layer 271.

Referring to FIG. 8, descriptions below focus on the differences from the integrated circuit device 210 described herein with reference to FIG. 6.

According to some embodiments, a dielectric wall DW may be disposed between the first gate line 261 and the second gate line 262 of an integrated circuit device 230. The dielectric wall DW may include a dielectric material. According to some embodiments, the dielectric wall DW may be disposed in contact with a first nano-sheet N211, a second nano-sheet N212, and a third nano-sheet N213 included in the first nano-sheet stack NSS21, and may be disposed in contact with a first nano-sheet N221, a second nano-sheet N222, and a third nano-sheet N223 included in the second nano-sheet stack NSS22.

According to some embodiments, the dielectric wall DW may be a type of the vertical structure VS described herein with reference to FIG. 1, FIG. 2A, FIG. 2B, FIG. 3A, and FIG. 3B. In detail, the vertical structure VS disposed between the first region 202_1 and the second region 202_2 of the integrated circuit device 230, which are doped with different conductivity types, may be referred to as the dielectric wall DW.

According to some embodiments, the first region 202_1 and the second region 202_2 of an integrated circuit device 230 may be doped with different conductivity types. For example, the first region 202_1 of the integrated circuit device 230 may be an nFET region, and the second region 202_2 may be a pFET region. In other words, a transistor TR31 formed on a portion of the first region 202_1 of the integrated circuit device 230 at which the first fin-type active region FA21 and the first gate line 261 intersect each other may be an nFET, and a transistor TR32 formed on a portion of the second region 202_2 of the integrated circuit device 230 at which the second fin-type active region FA22 and the second gate line 262 intersect each other may be a pFET.

According to some embodiments, the second metal layer 272 may be disposed on the first gate dielectric layer 251, and the first metal layer 271 and the second metal layer 272 may be arranged on the second gate dielectric layer 252. In detail, on the first region 202_1 of the substrate 202, the second metal layer 272 may be disposed between the first gate dielectric layer 251 and the first gate line 261, and the first metal layer 271 may be omitted in the first region 202_1. In detail, on the second region 202_2 of the substrate 202, the first metal layer 271 and the second metal layer 272 may be arranged between the second gate dielectric layer 252 and the second gate line 262. For example, on the second region 202_2 of the substrate 202, the second metal layer 272 may be spaced apart from the second gate dielectric layer 252 with the first metal layer 271 disposed therebetween.

Referring to FIG. 9, an integrated circuit device 300 may include a first fin-type active region FA31 extending in the first horizontal direction (X direction) on a first region 302_1 of a substrate 302, a second fin-type active region FA32 extending in the first horizontal direction (X direction) on a second region 3022 of the substrate 302 and spaced apart from the first fin-type active region FA31 in the second horizontal direction (Y direction), and a third fin-type active region FA33 extending in the first horizontal direction (X direction) on a third region 302_3 of the substrate 302 and spaced apart from the second fin-type active region FA32 in the second horizontal direction (Y direction).

According to some embodiments, a first gate line 361 may be disposed on the first fin-type active region FA31, a second gate line 362 may be disposed on the second fin-type active region FA32, and a third gate line 363 may be disposed on the third fin-type active region FA33. The first gate line 361 and the second gate line 362 may extend in the second horizontal direction (Y direction) and may be spaced apart from each other in the second horizontal direction (Y direction) with the cutting structure CTS disposed therebetween. The second gate line 362 and the third gate line 363 may extend in the second horizontal direction (Y direction) and may be spaced apart from each other in the second horizontal direction (Y direction) with the dielectric wall DW disposed therebetween.

According to some embodiments, a first nano-sheet stack NSS31 may be disposed on a fin top surface of the first fin-type active region FA31. The first nano-sheet stack NSS31 may include a first plurality of nano-sheets surrounded by the first gate line 361.

In the same regard, a second nano-sheet stack NSS32 may be disposed on a fin top surface of the second fin-type active region FA32, and a third nano-sheet stack NSS33 may be disposed on a fin top surface of the third fin-type active region FA33. The second nano-sheet stack NSS32 may include a second plurality of nano-sheets and the third nano-sheet stack NSS33 may include a third plurality of nano-sheets.

According to some embodiments, the first plurality of nano-sheets may include a first nano-sheet N311, a second nano-sheet N312, and a third nano-sheet N313, the second plurality of nano-sheets may include a first nano-sheet N321, a second nano-sheet N322, and a third nano-sheet N323, and the third plurality of nano-sheets may include a first nano-sheet N331, a second nano-sheet N332, and a third nano-sheet N333.

According to some embodiments, the first nano-sheet stack NSS31 and the second nano-sheet stack NSS32 may be spaced apart from each other in the second horizontal direction (Y direction) with the cutting structure CTS disposed therebetween. According to some embodiments, the second nano-sheet stack NSS32 and the third nano-sheet stack NSS33 may be spaced apart from each other in the second horizontal direction (Y direction) with the dielectric wall DW disposed therebetween.

According to some embodiments, the cutting structure CTS may be disposed between the first gate line 361 and the second gate line 362. The cutting structure CTS may be disposed in contact with the first plurality of nano-sheets included in the first nano-sheet stack NSS31 and may be disposed in contact with the second plurality of nano-sheets included in the second nano-sheet stack NSS32, between the first nano-sheet stack NSS31 and the second nano-sheet stack NSS32. In detail, the cutting structure CTS may be disposed in contact with the first nano-sheet N311, the second nano-sheet N312, and the third nano-sheet N313 included in the first plurality of nano-sheets, and disposed in contact with the first nano-sheet N321, the second nano-sheet N322, and the third nano-sheet N323 included in the second plurality of nano-sheets.

According to some embodiments, the dielectric wall DW may be disposed between the second gate line 362 and the third gate line 363. The dielectric wall DW may be disposed in contact with the second plurality of nano-sheets included in the second nano-sheet stack NSS32 and may be disposed in contact with the third plurality of nano-sheets included in the third nano-sheet stack NSS33, between the second nano-sheet stack NSS32 and the third nano-sheet stack NSS33. In detail, the dielectric wall DW may be disposed in contact with the first nano-sheet N321, the second nano-sheet N322, and the third nano-sheet N323 included in the second plurality of nano-sheets, and disposed in contact with the first nano-sheet N331, the second nano-sheet N332, and the third nano-sheet N333 included in the third plurality of nano-sheets.

According to some embodiments, the first region 302_1 and the second region 302_2 of an integrated circuit device 300 may be doped with the same conductivity type. For example, both the first region 302_1 and the second region 302_2 of the integrated circuit device 300 may be nFET regions. On the other hand, the third region 3023 of the integrated circuit device 300 may be doped with a conductivity type different from that of the second region 302_2. For example, the second region 302_2 may be an nFET region and the third region 302_3 may be a pFET region.

In other words, a transistor TR41 formed at the intersection of the first fin-type active region FA31 and the first gate line 361 on the first region 302_1 of the integrated circuit device 300, and a transistor TR42 formed at the intersection of the second fin-type active region FA32 and the second gate line 362 on the second region 3022 of the integrated circuit device 300, may be nFETs, and a transistor TR43 formed at the intersection of the third fin-type active region FA33 and the third gate line 363 on the third region 302_3 of the integrated circuit device 300 may be a pFET.

According to some embodiments, a first gate dielectric layer 351 may include a first portion disposed between the first gate line 361 and the first nano-sheet stack NSS31 and a second portion disposed between a plurality of first sub-gate portions 361S and the cutting structure CTS. According to some embodiments, a thickness of the second portion in the second horizontal direction (Y direction) may be greater than a thickness of the first portion in the vertical direction (Z direction) and/or a thickness of the first portion in the second horizontal direction (Y direction).

According to some embodiments, a second gate dielectric layer 352 may include a first portion disposed between the second gate line 362 and the second nano-sheet stack NSS32 and a second portion disposed between a plurality of second sub-gate portions 362S and the cutting structure CTS and between the plurality of second sub-gate portions 362S and the dielectric wall DW. According to some embodiments, a thickness of the second portion in the second horizontal direction (Y direction) may be greater than a thickness of the first portion in the vertical direction (Z direction) and/or a thickness of the first portion in the second horizontal direction (Y direction). According to some embodiments, the thickness of a first sub-portion of the second portion disposed between the plurality of second sub-gate portions 362S and the cutting structure CTS in the second horizontal direction (Y direction) may be different from the thickness of a second sub-portion disposed between the plurality of second sub-gate portions 362S and the dielectric wall DW in the second horizontal direction (Y direction).

According to some embodiments, the third gate dielectric layer 353 may include a first portion disposed between the third gate line 363 and the third nano-sheet stack NSS33 and a second portion disposed between a plurality of third sub-gate portions 363S and the dielectric wall DW. According to some embodiments, a thickness of the second portion in the second horizontal direction (Y direction) may be greater than a thickness of the first portion in the vertical direction (Z direction) and/or a thickness of the first portion in the second horizontal direction (Y direction).

According to some embodiments, a second metal layer 372 may be disposed on the first gate dielectric layer 351 and the second gate dielectric layer 352, and a first metal layer 371 and the second metal layer 372 may be arranged on a third gate dielectric layer 353. In detail, the second metal layer 372 may be disposed between the first gate dielectric layer 351 and the first gate line 361 on the first region 302_1 and the second region 302_2 of the substrate 302. In detail, on the third region 302_3 of the substrate 302, the first metal layer 371 and the second metal layer 372 may be arranged between the third gate dielectric layer 353 and the third gate line 363. The first metal layer 371 may be omitted from the first region 302_1 and the second region 302_2 of the substrate 302.

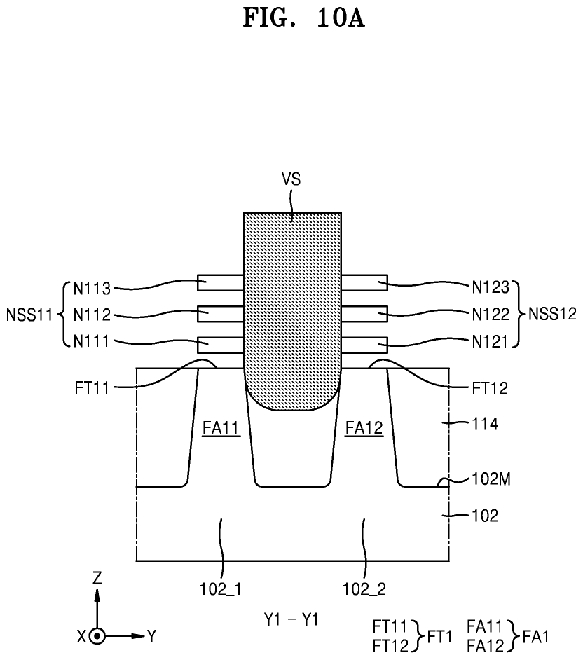

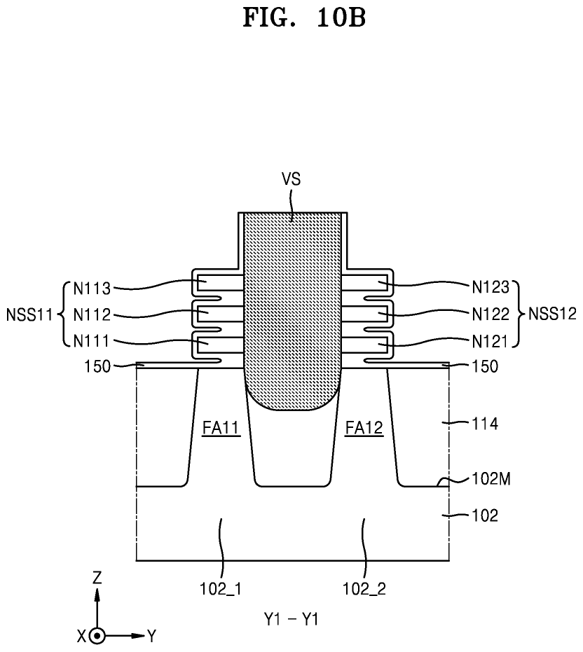

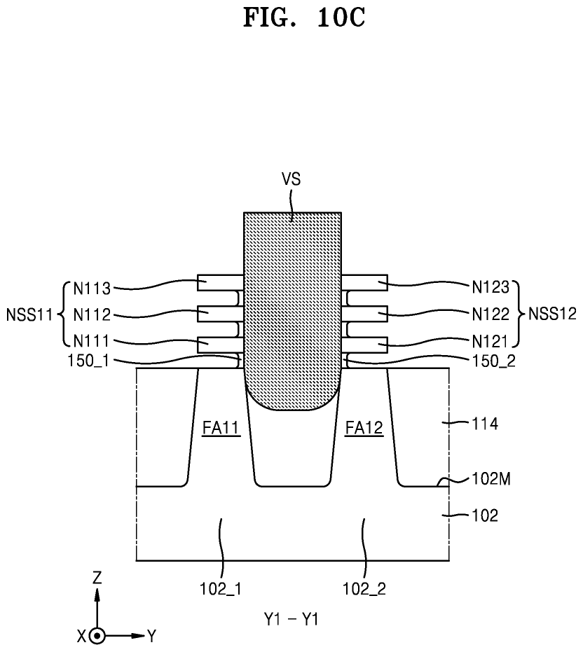

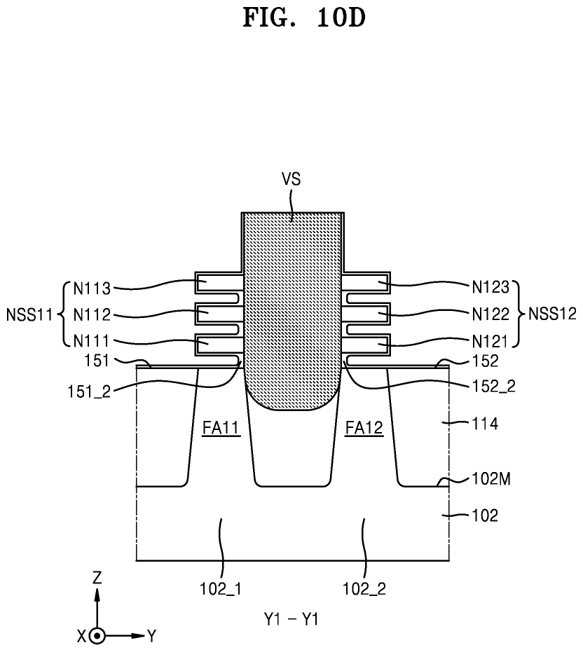

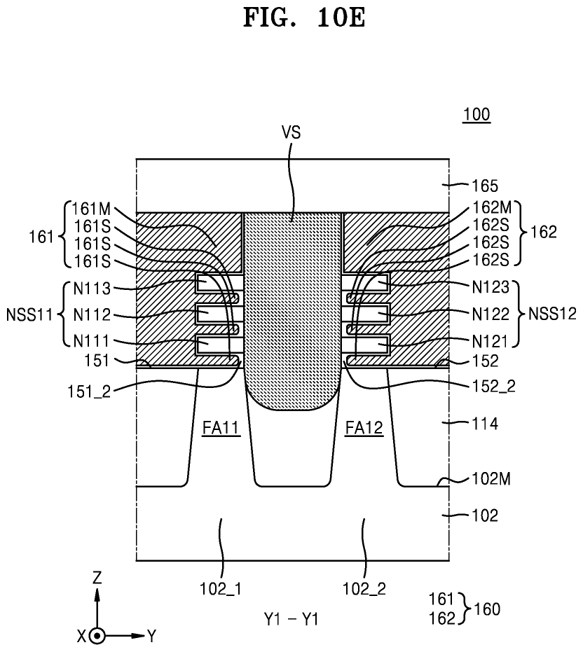

FIG. 10A, FIG. 10B, FIG. 10C, FIG. 10D, and FIG. 10E are cross-sectional views for describing a method of manufacturing an integrated circuit device according to embodiments. In detail, FIGS. 10A to 10E are cross-sectional views for describing some of operations of a method of manufacturing the integrated circuit device 100 described herein with reference to FIG. 1, FIG. 2A, FIG. 2B, FIG. 3A, and FIG. 3B.

Referring to FIG. 10A, the plurality of fin-type active regions FA1 may be defined on the substrate 102 by partially etching the substrate 102. Thereafter, the device isolation layer 114 covering sidewalls of each of the plurality of fin-type active regions FA1 may be formed.

Nano-sheet stacks NSS11 and NSS12 respectively including a plurality of nano-sheets N111 to N113 and a plurality of nano-sheets N121 to N123 may be formed on the fin top surfaces FT1 of the plurality of fin-type active regions FA1.

The vertical structure VS contacting each of the plurality of nano-sheet stacks NSS11 and NSS12 may be formed. The vertical structure VS may be formed by etching between the plurality of nano-sheet stacks NSS1 and forming an insulation material in a space formed through the etching. The insulation material may fill the space formed through the etching. The vertical structure VS may be formed by etching portions of the device isolation layer 114 between the plurality of fin-type active regions FA1.

Referring to FIG. 10B, a pre-dielectric layer 150 may be formed on sidewalls of the vertical structure VS and the plurality of nano-sheet stacks NSS1. The pre-dielectric layer 150 may cover the sidewalls of the vertical structure VS and the plurality of nano-sheet stacks NSS1.

In detail, on the first region 102_1 of the substrate 102, the pre-dielectric layer 150 may be disposed on a top surface of the device isolation layer 114, on top surfaces, side surfaces, and bottom surfaces of the first nano-sheet N111, the second nano-sheet N112, and the third nano-sheet N113 included in the first nano-sheet stack NSS11, and between the first nano-sheet N111 and the first fin-type active region FA11. In particular, the pre-dielectric layer 150 may be disposed between the first nano-sheet N111, the second nano-sheet N112, and the third nano-sheet N113 and between the first nano-sheet N111 and the first fin-type active region FA11 to overlap the vertical structure VS in the second horizontal direction (Y direction).

In detail, on the second region 102_2 of the substrate 102, the pre-dielectric layer 150 may be disposed on the top surface of the device isolation layer 114, on top surfaces, side surfaces, and bottom surfaces of the first nano-sheet N121, the second nano-sheet N122, and the third nano-sheet N123 included in the second nano-sheet stack NSS12, and between the first nano-sheet N121 and the second fin-type active region FA12. In particular, the pre-dielectric layer 150 may be disposed between the first nano-sheet N121, the second nano-sheet N122, and the third nano-sheet N123 and between the first nano-sheet N121 and the second fin-type active region FA12 to overlap the vertical structure VS in the second horizontal direction (Y direction).

Referring to FIG. 10C, a portion of the pre-dielectric layer 150 may be removed. In detail, the portion of the pre-dielectric layer 150 may be removed from the first region 102_1 of the substrate 102, except for a first portion 1501 disposed between the first nano-sheet N111, the second nano-sheet N112, and the third nano-sheet N113 and between the first nano-sheet N111 and the first fin-type active region FA11. In detail, the portion of the pre-dielectric layer 150 may be removed from the second region 102_2 of the substrate 102, except for a second portion 150_2 disposed between the first nano-sheet N121, the second nano-sheet N122, and the third nano-sheet N123 and between the first nano-sheet N121 and the second fin-type active region FA12.

Referring to FIG. 10D, the first gate dielectric layer 151 and the second gate dielectric layer 152 may be formed on sidewalls of the vertical structure VS and the plurality of nano-sheet stacks NSS1. The first gate dielectric layer 151 and the second gate dielectric layer 152 may be formed to cover sidewalls of the vertical structure VS and the plurality of nano-sheet stacks NSS1.

In detail, the first gate dielectric layer 151 may be formed between the first nano-sheet stack NSS11 and the first gate line 161 and between the first gate line 161 and the vertical structure VS. In detail, the second gate dielectric layer 152 may be formed between the second nano-sheet stack NSS12 and the second gate line 162 and between the second gate line 162 and the vertical structure VS.

Here, the first portion 150_1 and the second portion 150_2 of FIG. 10C may be integrated with the first gate dielectric layer 151 and the second gate dielectric layer 152, respectively. In detail, the first gate dielectric layer 151 may include the second portion 1512 disposed on the sidewalls of the vertical structure VS between the first nano-sheet N111, the second nano-sheet N112, and the third nano-sheet N113, and between the first nano-sheet N111 and the first fin-type active region FA11, wherein the second portion 151_2 may be formed as the first portion 150_1 of FIG. 10C and may be integrated with the first gate dielectric layer 151. In detail, the second gate dielectric layer 152 may include the second portion 152_2 disposed on the sidewalls of the vertical structure VS between the first nano-sheet N121, the second nano-sheet N122, and the third nano-sheet N123, and between the first nano-sheet N121 and the second fin-type active region FA12, wherein the second portion 1522 may be formed as the second portion 150_2 of FIG. 10C and may be integrated with the second gate dielectric layer 152.

Referring to FIG. 10E, the first gate line 161 may be formed on the first gate dielectric layer 151 on the first region 102_1 of the substrate 102. The first gate line 161 may be spaced apart from the first nano-sheet stack NSS11 and the vertical structure VS with the first gate dielectric layer 151 disposed therebetween. In the same regard, the second gate line 162 may be formed on the second gate dielectric layer 152 on the second region 102_2 of the substrate 102. The second gate line 162 may be spaced apart from the second nano-sheet stack NSS12 and the vertical structure VS with the second gate dielectric layer 152 disposed therebetween. The capping insulation pattern 165 may be disposed on top surfaces of the first gate dielectric layer 151, the second gate dielectric layer 152, the first gate line 161, and the second gate line 162. In detail, the top surfaces of the first gate dielectric layer 151, the second gate dielectric layer 152, the first gate line 161, and the second gate line 162 may be covered by the capping insulation pattern 165. The integrated circuit device 100 may be manufactured by performing a method of FIG. 10A, FIG. 10B, FIG. 10C, FIG. 10D, and FIG. to 10E.

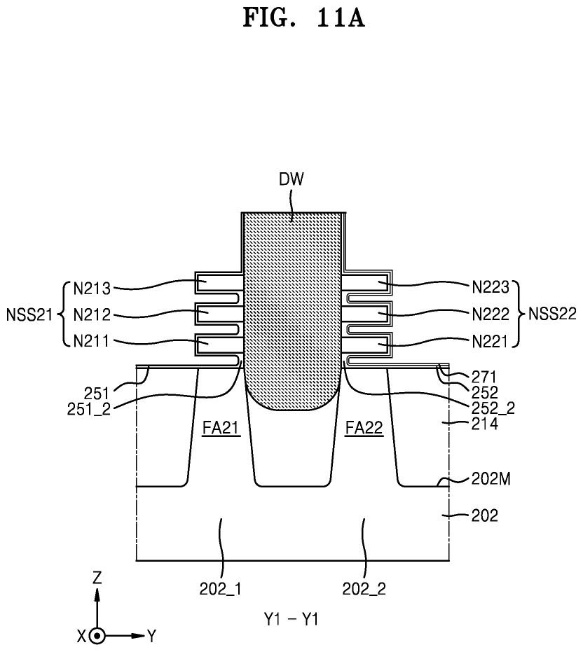

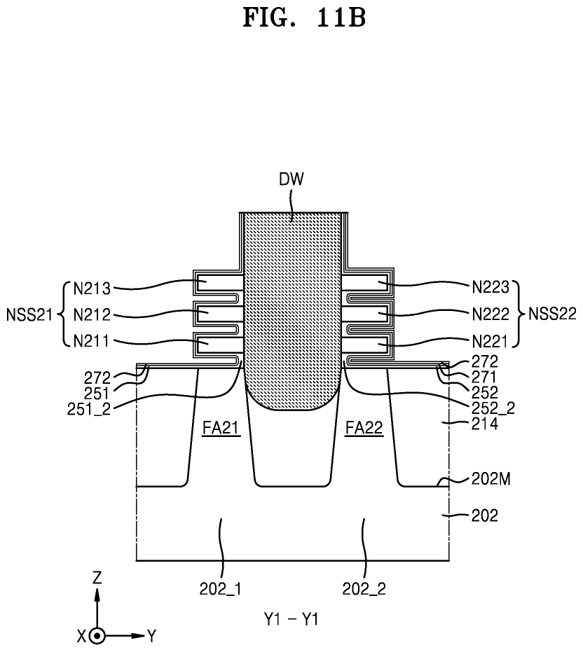

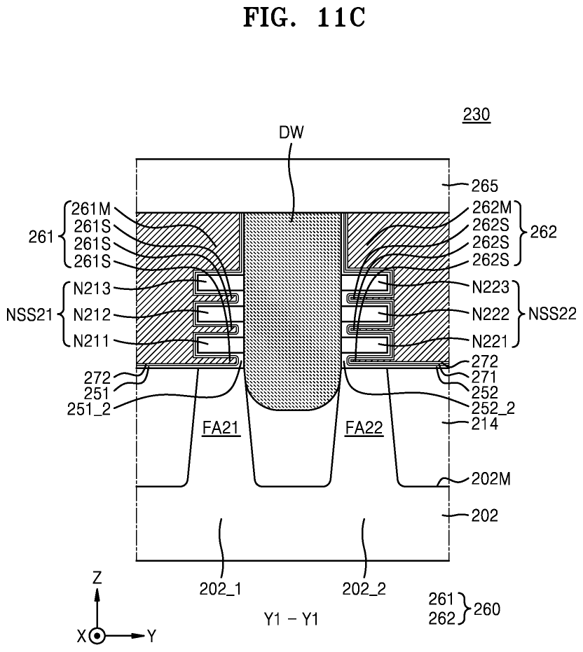

FIG. 11A, FIG. 11B, and FIG. 11C are cross-sectional views for describing a method of manufacturing an integrated circuit device according to embodiments. In detail, FIG. 11A, FIG. 11B, and FIG. 11C are cross-sectional views for describing some of operations of a method of manufacturing the integrated circuit device 230 described herein with reference to FIG. 8. FIG. 11A may be provided by performing a method of manufacturing an integrated circuit device described herein with reference to FIG. 10A, FIG. 10B, FIG. 10C, and FIG. 10D.

Referring to FIG. 11A, the first metal layer 271 may be disposed on the second region 202_2 of the substrate 202. In detail, the first metal layer 271 may be disposed on the second gate dielectric layer 252.

Referring to FIG. 11B, the second metal layer 272 may be disposed on the first region 202_1 and the second region 202_2 of the substrate 202. In detail, the second metal layer 272 may be disposed on the first gate dielectric layer 251 on the first region 202_1 of the substrate 202. In detail, the second metal layer 272 may be disposed on the first metal layer 271 on the second region 202_2 of the substrate 202. For example, the second metal layer 272 may be spaced apart from the second gate dielectric layer 252 with the first metal layer 271 disposed therebetween.

Referring to FIG. 11C, the first gate line 261 may be formed on the first gate dielectric layer 251 on the first region 202_1 of the substrate 202. The first gate line 261 may be spaced apart from the first nano-sheet stack NSS21 and the dielectric wall DW with the first gate dielectric layer 251 disposed therebetween. In the same regard, a second gate line 262 may be formed on the second gate dielectric layer 252 on the second region 202_2 of the substrate 202. A capping insulation pattern 265 may be disposed on top surfaces of the first gate dielectric layer 251, the second gate dielectric layer 252, the first gate line 261, and the second gate line 262. In detail, the top surfaces of the first gate dielectric layer 251, the second gate dielectric layer 252, the first gate line 261, and the second gate line 262 may be covered by the capping insulation pattern 265. The integrated circuit device 230 may be manufactured by performing a method of FIG. 11A, FIG. 11B, and FIG. 11C.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a first fin-type active region extending in a first horizontal direction on a substrate;
a first nano-sheet stack comprising a first plurality of nano-sheets arranged on the first fin-type active region;
a first gate line extending in a second horizontal direction intersecting the first horizontal direction, on the first fin-type active region;
a vertical structure contacting each of the first plurality of nano-sheets included in the first nano-sheet stack; and
a first gate dielectric layer disposed between the first gate line and the first plurality of nano-sheets and between the first gate line and the vertical structure,
wherein the first gate line comprises a first sub-gate portion disposed under each of the first plurality of nano-sheets,
the first gate dielectric layer comprises:
a first portion disposed between the first gate line and the first plurality of nano-sheets; and
a second portion disposed between the first sub-gate portion and the vertical structure, and
a thickness of the second portion in the second horizontal direction is greater than a thickness of the first portion in a vertical direction.

2. The integrated circuit device of claim 1, further comprising a first source/drain region disposed adjacent to the first gate line and contacting each of the first plurality of nano-sheets,
wherein the first gate line further comprises a first main gate portion disposed on the first nano-sheet stack,
the first gate dielectric layer further comprises a third portion disposed between the first sub-gate portion and the first source/drain region, and
a thickness of the third portion in the first horizontal direction is greater than the thickness of the first portion in the vertical direction.

3. The integrated circuit device of claim 1, wherein the first gate dielectric layer comprises a stacked structure comprising an interfacial dielectric layer and a high-k layer.

4. The integrated circuit device of claim 1, wherein the thickness of the second portion in the second horizontal direction increases toward the first portion.

5. The integrated circuit device of claim 1, wherein the first plurality of nano-sheets comprise a first nano-sheet, a second nano-sheet on the first nano-sheet, and a third nano-sheet on the second nano-sheet,
the second portion comprises:
a first sub-portion disposed between the first nano-sheet and the second nano-sheet; and
a second sub-portion disposed between the second nano-sheet and the third nano-sheet, and
a thickness of the first sub-portion in the second horizontal direction and a thickness of the second sub-portion in the second horizontal direction are different from each other.

6. The integrated circuit device of claim 1, further comprising:
a second fin-type active region spaced apart from the first fin-type active region in the second horizontal direction and extending in the first horizontal direction;
a second nano-sheet stack disposed on the second fin-type active region, spaced apart from the first nano-sheet stack with the vertical structure disposed therebetween, and comprising a second plurality of nano-sheets in contact with the vertical structure;
a second gate line extending in the second horizontal direction, on the second fin-type active region, and spaced apart from the first gate line with the vertical structure disposed therebetween; and
a second gate dielectric layer disposed between the second gate line and the second plurality of nano-sheets and between the second gate line and the vertical structure,
wherein the second gate line comprises:
a second main gate portion disposed on the second nano-sheet stack; and
a second sub-gate portion disposed under each of the second plurality of nano-sheets,
the second gate dielectric layer comprises:
a first portion disposed between the second gate line and the second plurality of nano-sheets; and
a second portion disposed between the second sub-gate portion and the vertical structure, and
a thickness of the second portion in the second horizontal direction is greater than the thickness of the first portion in the vertical direction.

7. An integrated circuit device comprising:
a substrate comprising a first region and a second region;
a first fin-type active region extending in a first horizontal direction on the first region;
a second fin-type active region extending in the first horizontal direction on the second region and spaced apart from the first fin-type active region in a second horizontal direction intersecting the first horizontal direction;
a plurality of nano-sheets on the first fin-type active region and the second fin-type active region and spaced apart from the first fin-type active region and the second fin-type active region in a vertical direction;
a first gate line on the first fin-type active region and extending in the second horizontal direction;
a second gate line on the second fin-type active region and extending in the second horizontal direction;
a vertical structure disposed between the first gate line and the second gate line and contacting each of the plurality of nano-sheets; and
a first gate dielectric layer disposed between the first gate line and the plurality of nano-sheets and between the first gate line and the vertical structure,
wherein the first gate line comprises:
a first main gate portion disposed at a higher vertical level than the plurality of nano-sheets on the first fin-type active region; and
a first sub-gate portion disposed under each of the plurality of nano-sheets on the first fin-type active region,
the first gate dielectric layer comprises:
a first portion disposed between the first gate line and the plurality of nano-sheets on the first fin-type active region; and
a second portion disposed between the first sub-gate portion and the vertical structure, and
a thickness of the second portion in the second horizontal direction is greater than the thickness of the first portion in the second horizontal direction.

8. The integrated circuit device of claim 7, wherein the first fin-type active region and the second fin-type active region have a same conductivity type, and
the vertical structure comprises an insulation material.

9. The integrated circuit device of claim 7, wherein the first fin-type active region and the second fin-type active region have different conductivity types, and
the vertical structure comprises a dielectric material.

10. The integrated circuit device of claim 9, wherein a first metal layer is disposed on the plurality of nano-sheets on the second fin-type active region, and
a second metal layer is disposed on the plurality of nano-sheets on the first fin-type active region and the second fin-type active region.

11. The integrated circuit device of claim 7, further comprising a second gate dielectric layer disposed between the second gate line and the plurality of nano-sheets on the second fin-type active region and between the second gate line and the vertical structure,
wherein the second gate line comprises:
a second main gate portion disposed at a higher vertical level than the plurality of nano-sheets on the second fin-type active region; and
a second sub-gate portion disposed under each of the plurality of nano-sheets on the second fin-type active region,
the second gate dielectric layer comprises:
a first portion disposed between the second gate line and the plurality of nano-sheets on the second fin-type active region; and
a second portion disposed between the second sub-gate portion and the vertical structure, and
a thickness of the second portion of the second gate dielectric layer in the second horizontal direction is greater than a thickness of the first portion of the second gate dielectric layer in the second horizontal direction.

12. The integrated circuit device of claim 11, wherein a thickness of the second portion of the first gate dielectric layer in the second horizontal direction is different from the thickness of the second portion of the second gate dielectric layer in the second horizontal direction.

13. The integrated circuit device of claim 7, further comprising a first source/drain region disposed adjacent to the first gate line and contacting each of the plurality of nano-sheets on the first fin-type active region, wherein the first gate dielectric layer further comprises:
a third portion disposed between the first sub-gate portion and the first source/drain region; and
a thickness of the third portion in the first horizontal direction is greater than the thickness of the first portion in the vertical direction.

14. The integrated circuit device of claim 7, wherein the first gate dielectric layer comprises a stacked structure of an interfacial dielectric layer and a high-k layer.

15. The integrated circuit device of claim 7, wherein a thickness of the second portion of the first gate line in the second horizontal direction is greater than a thickness of the first portion of the first gate line in the vertical direction.

16. The integrated circuit device of claim 7, further comprising a first source/drain region disposed adjacent to the first gate line and contacting each of the plurality of nano-sheets on the first fin-type active region, wherein the first gate dielectric layer further comprises:
a third portion disposed between the first sub-gate portion and the first source/drain region; and
a thickness of the third portion in the first horizontal direction is greater than a thickness of the first portion in the vertical direction.

17. An integrated circuit device comprising:
a substrate comprising a first region and a second region;
a first fin-type active region extending in a first horizontal direction on the first region;
a second fin-type active region extending in the first horizontal direction on the second region and spaced apart from the first fin-type active region in a second horizontal direction intersecting the first horizontal direction;
a first nano-sheet stack facing a top surface of the first fin-type active region at a position spaced apart from the top surface of the first fin-type active region and comprising a first plurality of nano-sheets having different vertical levels from each other;
a second nano-sheet stack facing a top surface of the second fin-type active region at a position spaced apart from the top surface of the second fin-type active region and comprising a second plurality of nano-sheets having different vertical levels;
a first gate line extending in the second horizontal direction on the first fin-type active region;
a second gate line extending in the second horizontal direction on the second fin-type active region;
a vertical structure disposed between the first gate line and the second gate line and contacting each of the first plurality of nano-sheets and each of the second plurality of nano-sheets;
a first source/drain region disposed adjacent to the first gate line and contacting each of the first plurality of nano-sheets;
a second source/drain region disposed adjacent to the second gate line and contacting each of the second plurality of nano-sheets;
a first gate dielectric layer disposed between the first gate line and the first plurality of nano-sheets and between the first gate line and the vertical structure, and comprising a stacked structure of a first interfacial dielectric layer and a first high-k layer; and
a second gate dielectric layer disposed between the second gate line and the second plurality of nano-sheets and between the second gate line and the vertical structure,
wherein the first gate line comprises:
a first main gate portion disposed on a top surface of the first nano-sheet stack; and
a first sub-gate portion disposed at a lower vertical level than each of the first plurality of nano-sheets,
the second gate line comprises:
a second main gate portion disposed on a top surface of the second nano-sheet stack; and
a second sub-gate portion disposed at a lower vertical level than each of the second plurality of nano-sheets,
the first gate dielectric layer comprises:
a first portion disposed between the first gate line and the first plurality of nano-sheets;
a second portion disposed between the first sub-gate portion and the vertical structure; and
a third portion disposed between the first sub-gate portion and the first source/drain region,
each of a thickness of the second portion of the first gate dielectric layer in the second horizontal direction and a thickness of the third portion of the first gate dielectric layer in the first horizontal direction is greater than the thickness of the first portion of the first gate dielectric layer in a vertical direction,
the second gate dielectric layer comprises:
a first portion disposed between the second gate line and the second plurality of nano-sheets; and
a second portion disposed between the second sub-gate portion and the vertical structure, and
a thickness of the second portion of the second gate dielectric layer in the second horizontal direction is greater than a thickness of the first portion of the second gate dielectric layer in the vertical direction.

18. The integrated circuit device of claim 17, wherein both the first region and the second region are nFET regions or pFET regions, and
the vertical structure comprises an insulation material.

19. The integrated circuit device of claim 17, wherein the first region is an nFET region,
the second region is a pFET region,
the vertical structure comprises a dielectric material,
a p-type metal layer is disposed between the second gate dielectric layer and the second gate line, and
an n-type metal layer is disposed between the first gate dielectric layer and the first gate line and between the p-type metal layer and the second gate line.

20. The integrated circuit device of claim 17, wherein the thickness of the second portion of the first gate dielectric layer in the second horizontal direction is different from the thickness of the second portion of the second gate dielectric layer in the second horizontal direction.
